(19) United States
(12) Patent Application Publication
(10) Pub. No.: US 2016/0237568 A1
(43) Pub. Date: Aug. 18, 2016

(54) SUBSTRATE PROCESSING APPARATUS AND NON-TRANSITORY COMPUTER READABLE RECORDING MEDIUM

(71) Applicant: HITACHI KOKUSAI ELECTRIC INC., Tokyo (JP)

(72) Inventor: Hideharu ITATANI, Toyama-shi (JP)

(73) Assignee: HITACHI KOKUSAI ELECTRIC INC., Tokyo (JP)

(21) Appl. No.: 14/672,956

(22) Filed: Mar. 30, 2015

(30) Foreign Application Priority Data
Feb. 12, 2015 (JP) 2015025282

(51) Int. Cl. C23C 16/455; C23C 16/458; C23C 16/52

(52) U.S. Cl. CPC C23C 16/45557; C23C 16/52; C23C 16/4584

(57) ABSTRACT

Provided is a substrate processing apparatus includes: a process chamber; a substrate support table; a rotation unit; a plurality of source gas supply structures; a source gas supply unit; a plurality of source gas exhaust structures; a plurality of source gas exhaust pipes; a source gas exhaust unit; a plurality of reactive gas supply structures; a reactive gas supply unit; a plurality of reactive gas exhaust structures; a plurality of reactive gas exhaust pipes; a reactive gas exhaust unit; a plurality of reactive gas pressure detectors; and a controller configured to control at least the source gas supply unit, the source gas exhaust unit, the reactive gas supply unit, the reactive gas exhaust unit and the plurality of reactive gas pressure detectors.

### CROSS-REFERENCE TO RELATED PATENT APPLICATION

This U.S. non-provisional patent application claims priority under 35 U.S.C. §119 of Japanese Patent Application No. 2015-025282, filed on Feb. 12, 2015 in the Japanese Patent Office, the entire contents of which are hereby incorporated by reference.

### BACKGROUND OF THE INVENTION

1. Field of the Invention

The present invention relates to a substrate processing apparatus and a non-transitory computer-readable recording medium.

2. Description of the Related Art

In general, a substrate processing apparatus performing a process such as a film forming process on a substrate such as a wafer is used in a process of manufacturing a semiconductor device. The process which the substrate processing apparatus performs includes, for instance, a film forming process based on an alternate supply method. In the film forming process based on the alternate supply method, a source gas supplying process, a purging process, a reactive gas supplying process and a purging process are used as one cycle, and the cycle is repeatedly performed on a substrate to be processed a predetermined number of times (n cycles), and thereby forming a film on the substrate. The substrate processing apparatus performing the film forming process may be configured to supply various gases (a source gas, a reactive gas, a purge gas, etc.) onto a surface of the substrate to be processed from above the substrate, and to discharge the various gases supplied onto the surface of the substrate through above the substrate (e.g., see Patent document 1).

In the case of this substrate processing apparatus, there are a substrate support table having a substrate placement surface on which a plurality of substrates are circumferentially placed, and a gas supplier installed at a position opposite to the substrate placement surface. The gas supplier has a structure in which a gas is alternately supplied in a rotational direction of the substrate support table. In the film forming process, a film is formed on the substrate while the substrate support table is rotated below the gas supplier. Whenever the substrate support table makes a round, a monolayer film is formed on the wafer. A plurality of rotations results in forming a multilayer film, and the substrate support table is rotated until the multilayer film reaches a desired thickness.

### RELATED ART DOCUMENTS

### Patent Documents

1. Japanese Unexamined Patent Application, First Publication No. 2011-222960

### SUMMARY OF THE INVENTION

When the formed film is used for, for instance, an electrode, it is necessary to make characteristics of the film uniform in a thickness direction of the film. The characteristics include, for instance, a resistance value. To achieve this, the conditions that each layer is formed are preferably consistent. For example, when the conditions are not consistent, the characteristics of the film become inconsistent, and thus a yield may be reduced.

An object of the present invention is to inhibit a film having inconsistent characteristics from being formed to process a substrate at a high yield.

According to one aspect of the present invention, there is provided a configuration including:

a process chamber;

a substrate support table disposed in the process chamber, the substrate support table including circumferentially arranged substrate placement units;

a rotation unit configured to rotate the substrate support table;

a plurality of source gas supply structures circumferentially arranged above the substrate support table;

a source gas supply unit configured to supply a source gas to a region below the plurality of source gas supply structures via the plurality of source gas supply structures;

a plurality of source gas exhaust structures configured to exhaust an atmosphere of the region below the plurality of source gas supply structures, wherein each source gas exhaust structure corresponds to each source gas supply structure;

a plurality of source gas exhaust pipes connected to the plurality of source gas exhaust structures, wherein each source gas exhaust pipe is connected to each source gas exhaust structure;

a source gas exhaust unit configured to exhaust an atmosphere of the process chamber via the plurality of source gas exhaust structures;

a plurality of reactive gas supply structures disposed between the plurality of source gas supply structures above the substrate support table;

a reactive gas supply unit configured to supply a reactive gas to a region below the plurality of reactive gas supply structures via the plurality of reactive gas supply structures;

a plurality of reactive gas exhaust structures configured to exhaust an atmosphere of the region below the plurality of reactive gas supply structures, wherein each reactive gas exhaust structure corresponds to each reactive gas supply structure;

a plurality of reactive gas exhaust pipes connected to the plurality of reactive gas exhaust structures, wherein each reactive gas exhaust pipe is connected to each reactive gas exhaust structure;

a reactive gas exhaust unit configured to exhaust the atmosphere of the process chamber via the plurality of reactive gas exhaust structures;

a plurality of reactive gas pressure detectors installed at the plurality of reactive gas exhaust pipes; and

a controller configured to control at least the source gas supply unit, the source gas exhaust unit, the reactive gas supply unit, the reactive gas exhaust unit and the plurality of reactive gas pressure detectors.

### BRIEF DESCRIPTION OF THE DRAWINGS

FIG. 1 is a schematic cross-sectional view of a cluster type substrate processing apparatus according to a first embodiment of the present invention.

FIG. 2 is a schematic longitudinal sectional view of the cluster type substrate processing apparatus according to the first embodiment of the present invention.

FIG. 3 is a schematic cross-sectional view of a process chamber with which the substrate processing apparatus according to the first embodiment of the present invention is equipped.

FIG. 4 is a schematic longitudinal sectional view of the process chamber with which the substrate processing apparatus according to the first embodiment of the present invention is equipped, and is a sectional view taken along line B-B′ of the process chamber illustrated in FIG. 3.

FIG. 5 is a schematic longitudinal sectional view of the process chamber with which the substrate processing apparatus according to the first embodiment of the present invention is equipped, and is a sectional view taken along line C-C′ of the process chamber illustrated in FIG. 3.

FIG. 6 is a schematic cross-sectional view of a gas supply/exhaust structure with which the substrate processing apparatus according to the first embodiment of the present invention is equipped, and is a sectional view taken along line D-D′ of the process chamber illustrated in FIG. 4.

FIG. 7 is a schematic cross-sectional view of a gas supply/exhaust structure with which the substrate processing apparatus according to the first embodiment of the present invention is equipped, and is a sectional view taken along line E-E′ of the process chamber illustrated in FIG. 4.

FIG. 8 is an explanatory view of a gas supply unit according to the first embodiment of the present invention.

FIG. 9 is an explanatory view of a gas exhaust unit according to the first embodiment of the present invention.

FIG. 10 is an explanatory view of a gas supply unit according to the first embodiment of the present invention.

FIG. 11 is an explanatory view of a gas exhaust unit according to the first embodiment of the present invention.

FIG. 12 is an explanatory view of a gas supply unit according to the first embodiment of the present invention.

FIG. 13 is a flowchart illustrating a process of processing a substrate according to the first embodiment of the present invention.

FIG. 14 is a flowchart of a film forming process according to the first embodiment of the present invention.

FIG. 15 is a flowchart describing an operation of a wafer in the film forming process according to the first embodiment of the present invention.

FIG. 16 is an explanatory view explaining a modification of the schematic cross-sectional view of the gas supply/exhaust structure with which the substrate processing apparatus according to the first embodiment of the present invention is equipped.

FIG. 17 is an explanatory view of a gas exhaust unit according to a second embodiment of the present invention.

FIG. 18 is an explanatory view of the gas exhaust unit according to the second embodiment of the present invention.

### DETAILED DESCRIPTION OF THE PREFERRED EMBODIMENTS

### First Embodiment of the Present Invention

### Configuration of Substrate Processing Apparatus

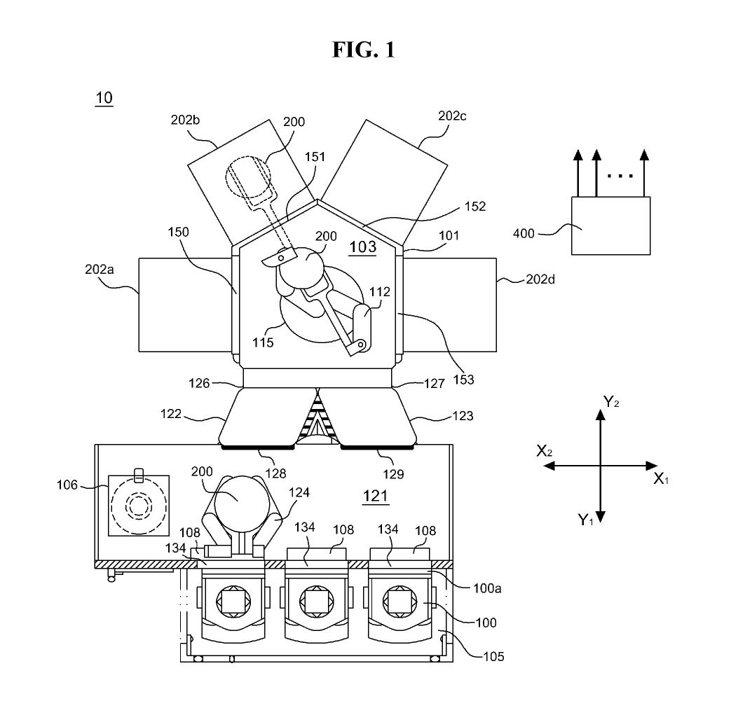

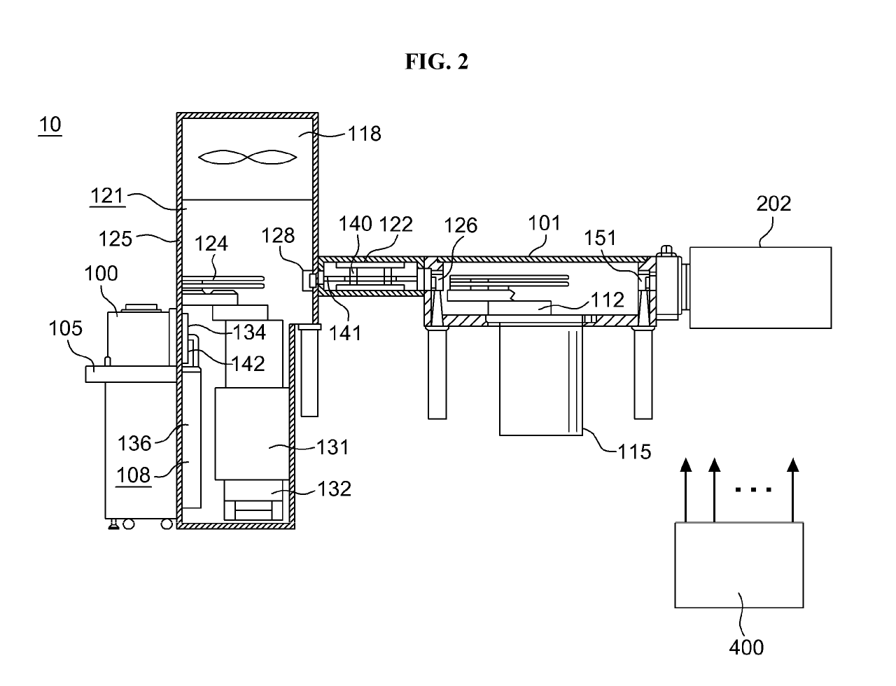

First, a substrate processing apparatus 10 according to the present embodiment will be described using FIGS. 1 and 2. FIG. 1 is a cross-sectional view of a cluster type substrate processing apparatus 10 according to the present embodiment. FIG. 2 is a schematic longitudinal sectional view of the cluster type substrate processing apparatus 10 according to the present embodiment.

In the substrate processing apparatus 10 to which the present invention is applied, a front opening unified pod 100 (hereinafter abbreviated to “FOUP”) is used as a carrier that carries a wafer 200 acting as a substrate. The carrier of the cluster type substrate processing apparatus 10 according to the present embodiment is divided into a vacuum side and an atmospheric side.

Further, the front, rear, left and right described below are based on FIG. 1. An X₁ direction shown in FIG. 1 is defined as the right, an X₂ direction as the left, a Y₁ direction as the front, and a Y₂ direction as the rear.

[Configuration of Vacuum Side]

As illustrated in FIGS. 1 and 2, the substrate processing apparatus 10 is equipped with a first conveyance chamber 103 capable of withstanding a pressure (negative pressure) that is less than atmospheric pressure, for instance, is in a vacuum state. A housing 101 of the first conveyance chamber 103 has, for instance, a pentagonal shape in a planar view, and is formed in a box shape in which both upper and lower ends are closed. Note that the “planar view” described below refers to when the substrate processing apparatus 10 is viewed from a vertical upper side thereof toward a vertical lower side thereof.

A first wafer transfer machine 112 capable of transferring two wafers 200 under negative pressure at the same time is installed in the first conveyance chamber 103. Here, the first wafer transfer machine 112 may transfer one wafer 200. The first wafer transfer machine 112 is configured to be elevated by a first wafer transfer machine elevator 115 while maintaining airtightness of the first conveyance chamber 103.

Spare chambers (load lock chambers) 122 and 123 are connected to a sidewall located at a front side among five sidewalls of the housing 101 via respective gate valves 126 and 127. The spare chambers 122 and 123 are configured to combine a function of loading the wafer 200 and a function of unloading the wafer 200, and are configured in a structure in which each thereof can withstand a negative pressure.

Further, the two wafers 200 can be placed in each of the spare chambers 122 and 123 in an overlapped state by a substrate support 140. A partition plate (middle plate) 141 disposed between the wafers 200 is installed in each of the spare chambers 122 and 123.

A first process chamber 202a, a second process chamber 202b, a third process chamber 202c and a fourth process chamber 202d, each of which performs a desired process on the substrate, are connected to the four sidewalls located at a rear side (back side) among the five sidewalls of the housing 101 of the first conveyance chamber 103 so as to be adjacent to one another via gate valves 150, 151, 152 and 153. The first process chamber 202a, the second process chamber 202b, the third process chamber 202c and the fourth process chamber 202d will be described below in detail.

[Configuration of Atmospheric Side]

A second conveyance chamber 121 capable of conveying the wafer 200 under vacuum and atmospheric pressure is connected to front sides of the spare chambers 122 and 123 via gate valves 128 and 129. A second substrate transfer machine 124 transferring the wafer 200 is installed in the second conveyance chamber 121. The second substrate transfer machine 124 is configured to be elevated by a second substrate transfer machine elevator 131 installed in the second conveyance chamber 121, and to be reciprocated in a leftward/rightward direction by a linear actuator 132.

A notch alignment device 106 is installed at a left side of the second conveyance chamber 121. Alternatively, the notch alignment device 106 may be an orientation flat alignment device. Further, a clean unit 118 supplying clean air is installed at an upper portion of the second conveyance chamber 121.

A substrate loading/unloading port 134 for loading or unloading the wafer 200 into or from the second conveyance chamber 121 and a FOUP opener 108 are installed at a front side of a housing 125 of the second conveyance chamber 121. A load port (10 stage) 105 is installed at a side opposite to the FOUP opener 108, i.e., at an outer side of the housing 125 via the substrate loading/unloading port 134. The FOUP opener 108 is equipped with a closure 142 that opens/closes a cap 100a of the FOUP 100 and can block the substrate loading/unloading port 134, and a drive mechanism 136 that drives the closure 142. Access of the wafer 200 to the FOUP 100 is allowed by opening/closing the cap 100a of the FOUP 100 placed on the load port 105. Further, the FOUP 100 is adapted to be supplied to and discharged from the load port 105 by an in-process conveyance device (OHT, etc.) which is not illustrated.

[Configuration of Process Chamber]

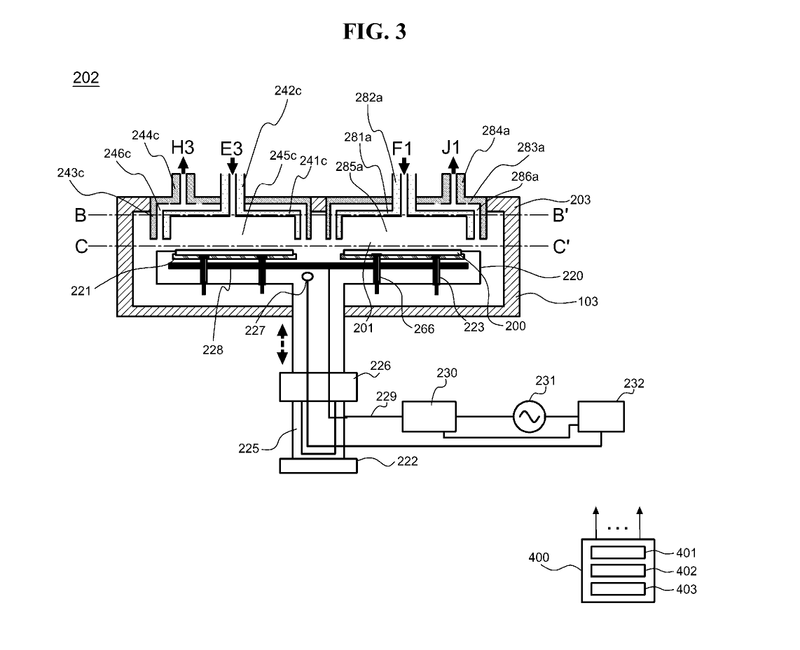

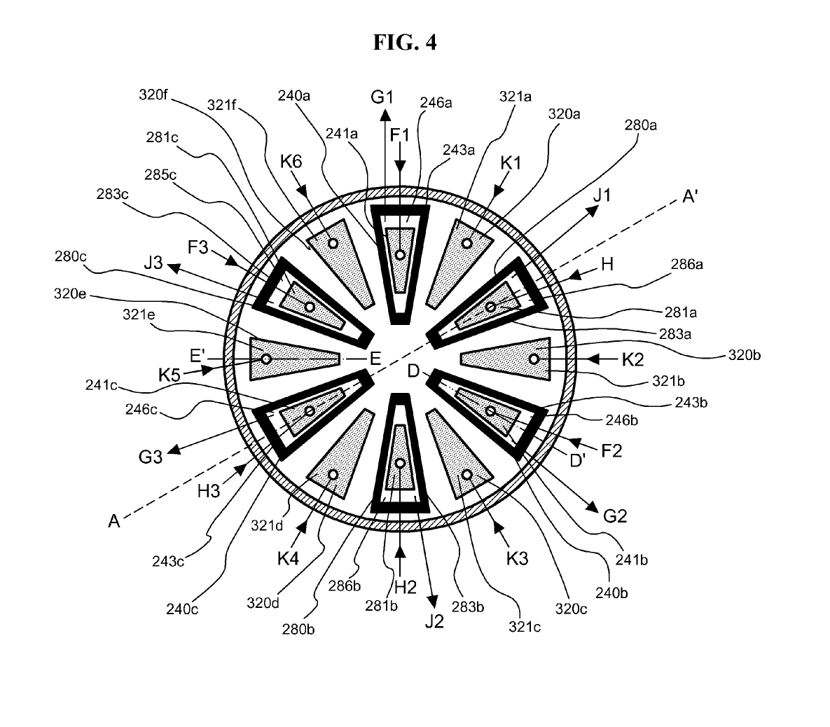

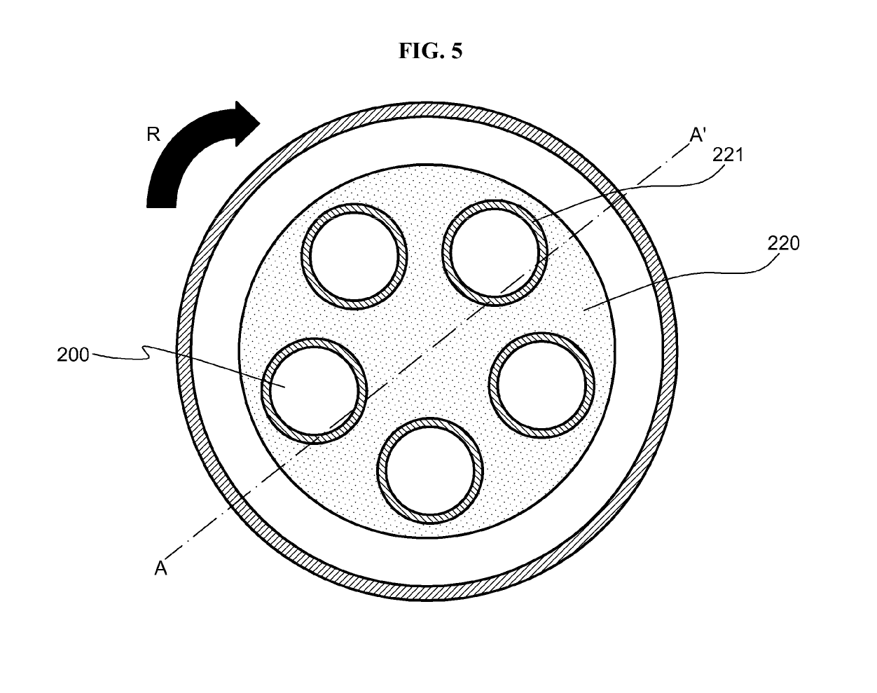

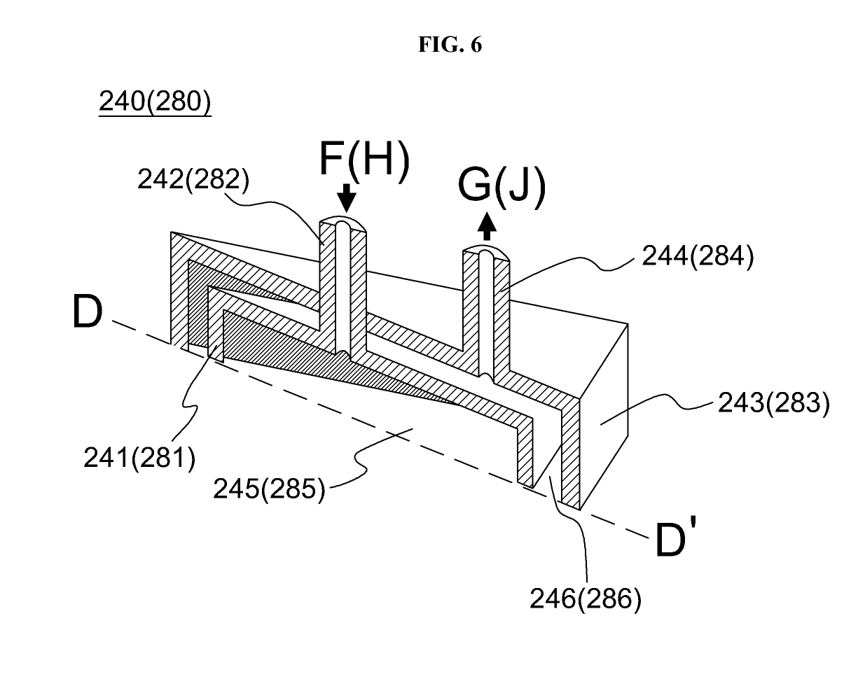

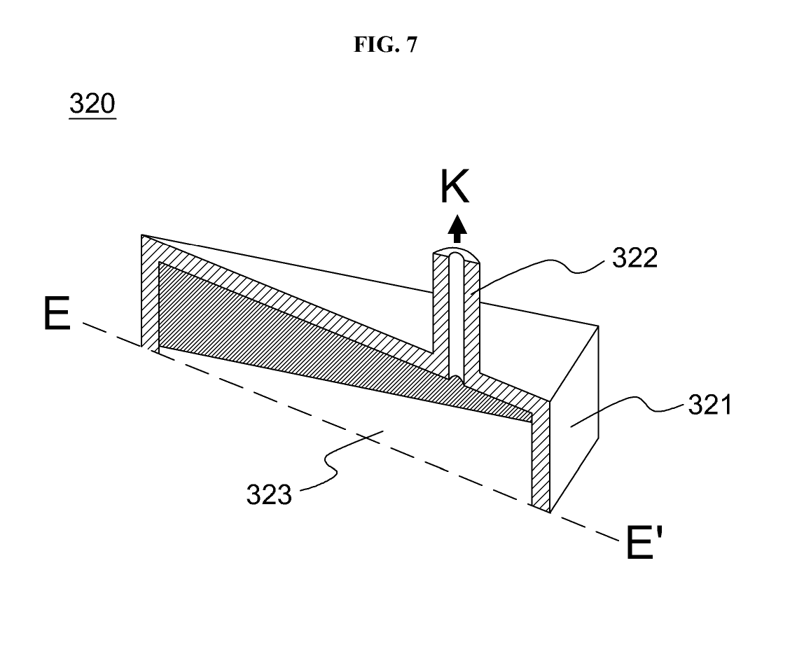

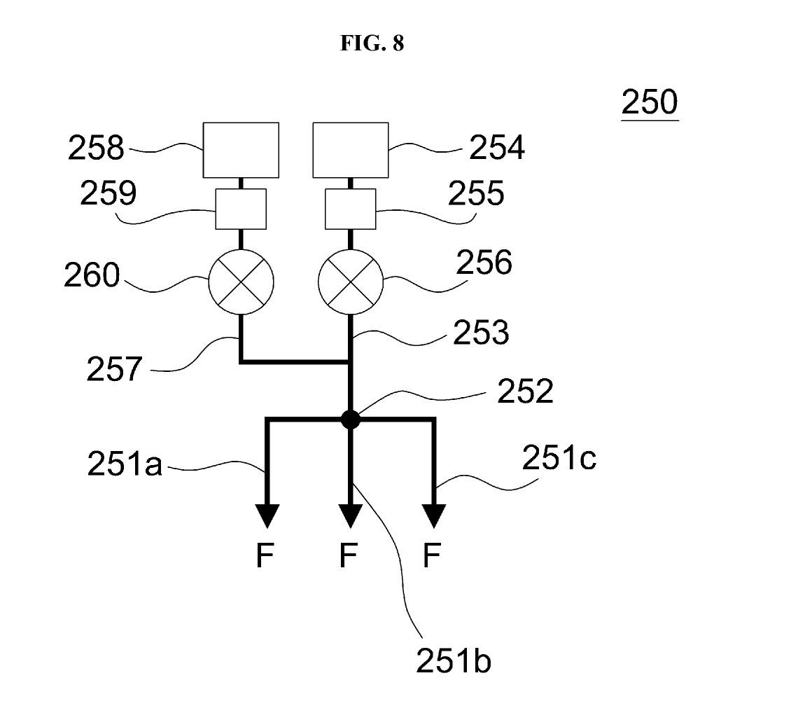

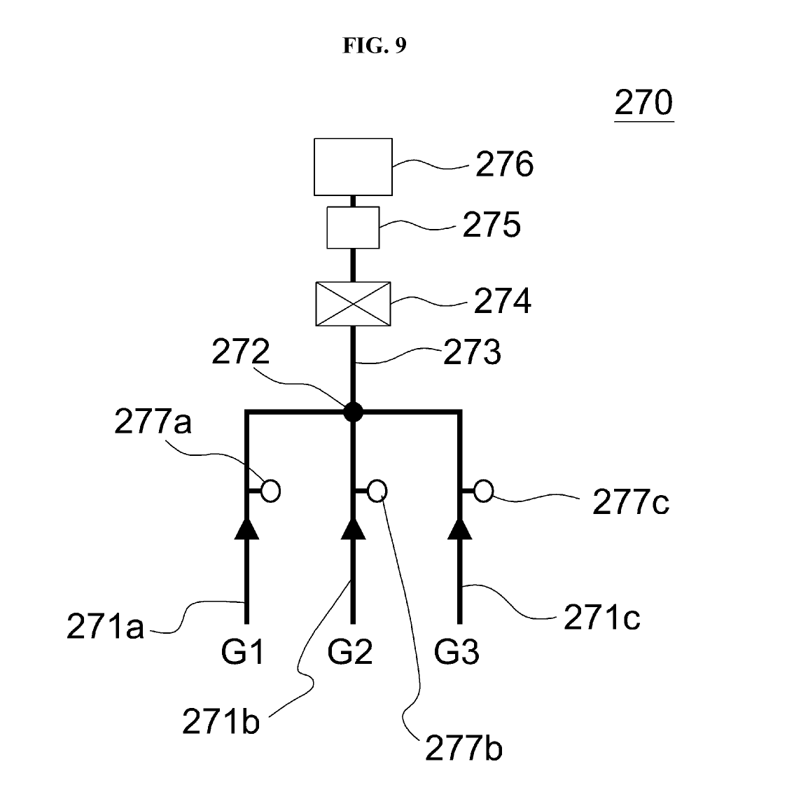

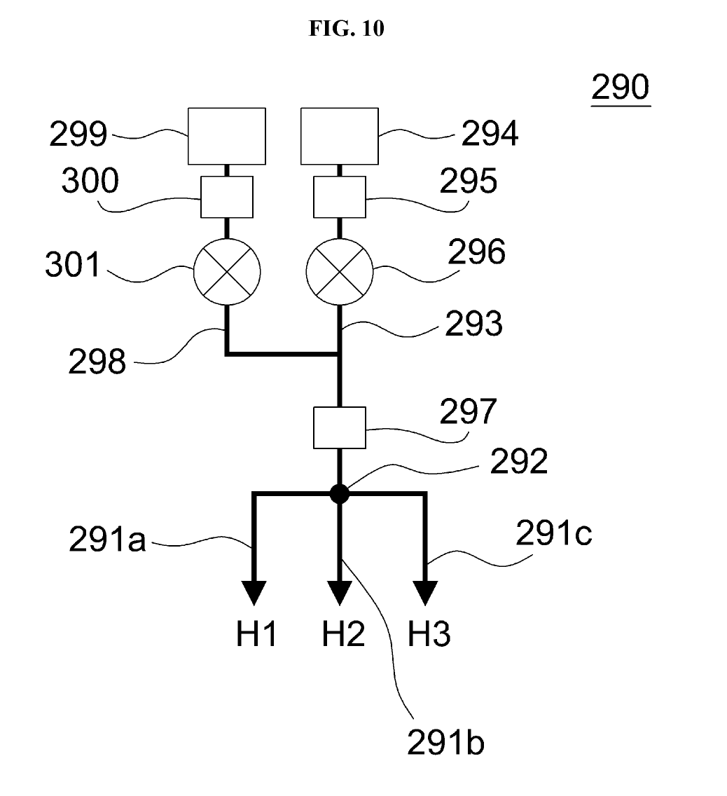

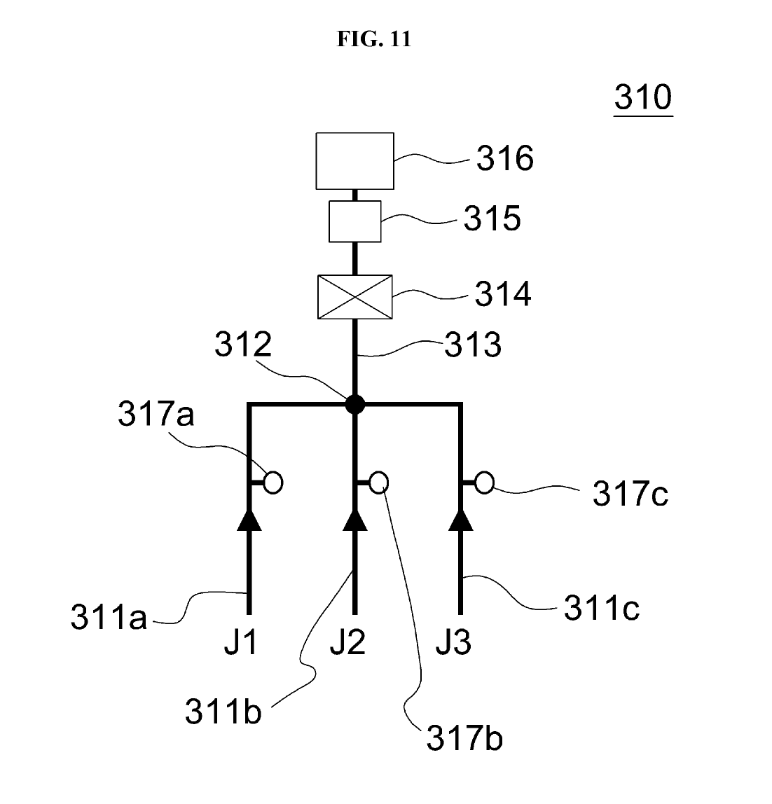

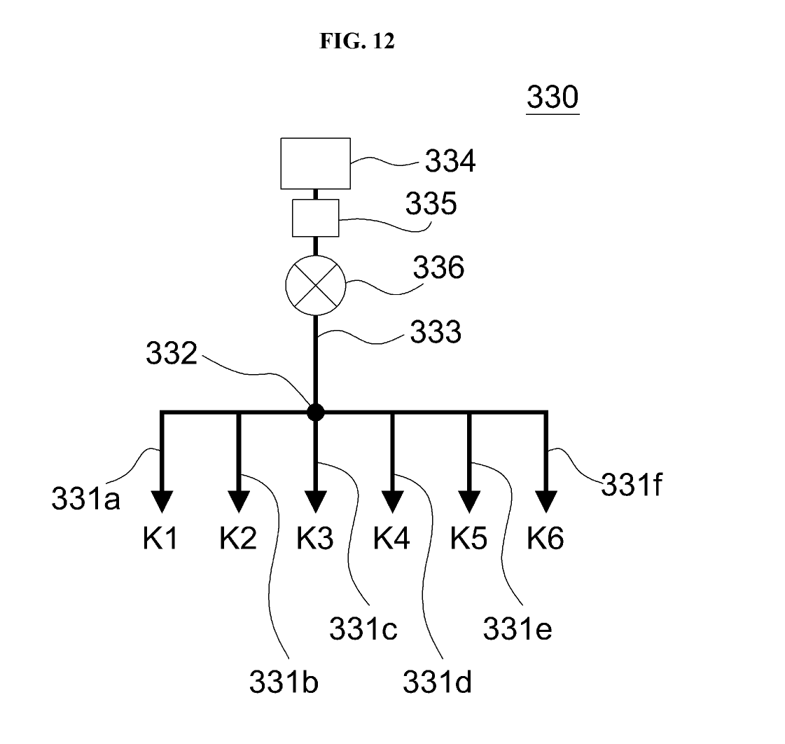

Subsequently, a configuration of the process chamber acting as a process furnace according to the present embodiment will be described using FIGS. 3 to 7. FIG. 3 is a schematic cross-sectional view of the process chamber with which the substrate processing apparatus 10 according to the present embodiment is equipped, and is a cross-sectional view taken along line A-A′ of FIG. 4 or 5. FIG. 4 is a schematic cross-sectional view of the process chamber with which the substrate processing apparatus 10 according to the present embodiment is equipped, and is a cross-sectional view taken along line B-B′ of the process chamber illustrated in FIG. 3. FIG. 5 is a schematic cross-sectional view of the process chamber with which the substrate processing apparatus 10 according to the present embodiment is equipped, and is a cross-sectional view taken along line C-C′ of the process chamber illustrated in FIG. 3. FIG. 6 is an explanatory view explaining a first gas supply/exhaust structure 240 and a second gas supply/exhaust structure 280. FIG. 7 is an explanatory view explaining a third gas supply structure 320. FIG. 8 is an explanatory view explaining a gas supply unit 250 supplying a first gas, and FIG. 9 is an explanatory view explaining a gas exhaust unit 270 exhausting the first gas. FIG. 10 is an explanatory view explaining a gas supply unit 290 supplying a second gas, and FIG. 11 is an explanatory view explaining a gas exhaust unit 310 exhausting the second gas. FIG. 12 is an explanatory view explaining a gas supply unit 330 supplying a third gas.

A relation between the configurations of FIGS. 4, 8, 9, 10, 11 and 12 will be described for the sake of convenience of description as follows. F1 of FIG. 4 is connected to F1 of FIG. 8. The same is true of F2 and F3. G1 of FIG. 4 is connected to G1 of FIG. 9. The same is true of G2 and G3. H1 of FIG. 4 is connected to H1 of FIG. 10. The same is true of H2 and H3. J1 of FIG. 4 is connected to J1 of FIG. 11. The same is true of J2 and J3. K1 of FIG. 4 is connected to K1 of FIG. 12. The same is true of K2 to K6.

In the present embodiment, the first process chamber 202a, the second process chamber 202b, the third process chamber 202c and the fourth process chamber 202d are configured to be identical to each other. Hereinafter, the first process chamber 202a, the second process chamber 202b, the third process chamber 202c and the fourth process chamber 202d are referred to collectively as a “process chamber 202.”

[Process Chamber]

As illustrated in FIGS. 3 to 5, the process chamber 202 acting as the process furnace is equipped with a reaction vessel 203 that is a cylindrical airtight vessel. A process room 201 processing the wafer 200 is formed in the reaction vessel 203.

A gas supply/exhaust structure 240 supplying a first gas, a gas supply/exhaust structure 280 supplying a second gas, and a gas supply structure 320 supplying an inert gas are installed upside in the reaction vessel 203. As illustrated in FIG. 4, the gas supply/exhaust structure 240, the gas supply structure 320, the gas supply/exhaust structure 280 and the gas supply structure 320 are alternately disposed in a rotational direction of a susceptor (substrate support table) 220 to be described below. For example, three gas supply/exhaust structures 240, three gas supply/exhaust structures 280 and six gas supply structures 320 are disposed.

In the plurality of gas supply/exhaust structures 240, a gas supply/exhaust structure 240a, a gas supply/exhaust structure 240b and a gas supply/exhaust structure 240c are disposed in that order in the rotational direction. In the plurality of gas supply/exhaust structures 280, a gas supply/exhaust structure 280a, a gas supply/exhaust structure 280b and a gas supply/exhaust structure 280c are disposed in that order in the rotational direction. In the plurality of gas supply structures 320, a gas supply structure 320a, a gas supply structure 320b, a gas supply structure 320c, a gas supply structure 320d and a gas supply structure 320f are disposed in that order in the rotational direction.

As described below, the wafer 200 placed on the susceptor 220 passes through regions below the three gas supply/exhaust structures 240, the three gas supply/exhaust structures 280 and the six gas supply structures 320. By passing through the below regions, whenever the susceptor 220 is rotated once, a plurality of films are formed. Due to this structure, a process having higher throughput than the related art is possible.

Further, as described below, the gas supply/exhaust structure 240 includes a gas supply structure 241 and a gas exhaust structure 243 configured to surround it in a horizontal direction. A gas supply channel 245 is formed inside the gas supply structure 241. Further, a gas exhaust channel 246 is formed between the gas supply structure 241 and the gas exhaust structure 243. Further, the gas supply/exhaust structure 280 includes a gas supply structure 281 and a gas exhaust structure 283 configured to surround it in a horizontal direction. A gas supply channel 285 is formed inside the gas supply structure 281. Further, a gas exhaust channel 286 is formed between the gas supply structure 281 and the gas exhaust structure 283.

Therefore, the first gas exhaust channel 246, the first gas supply structure 241, the first gas exhaust channel 246, the third gas supply structure 320, the second gas exhaust channel 286, the second gas supply structure 281, the second gas exhaust channel 286 and the third gas supply structure 320 are combined and disposed in turn in the rotational direction.

A lower end of each gas supply/exhaust structure and a lower end of each gas supply structure are disposed such near the susceptor 220 as to avoid interference with the wafer 200. Thereby, an amount of exposure of the gas to the wafer 200 is increased, and film thickness uniformization of the film formed on the wafer and an increase in use efficiency of the gas are realized.

As another method for increasing the amount of exposure of the gas, there is a method of increasing a pressure of the region below the gas supply structure. As the method of increasing the pressure, for example, there is a method of increasing an area of a bottom wall of the gas supply structure to make it difficult for the gas to leak out. When the pressure is increased, the pressure is controlled to be uniform in the regions below the gas supply/exhaust structure 240a, the gas supply/exhaust structure 240b and the gas supply/exhaust structure 240c. Thereby, process conditions of the gas supply/exhaust structure 240a, the gas supply/exhaust structure 240b and the gas supply/exhaust structure 240c can be equalized. As a result, characteristics of layers formed when passing through the respective below regions can be equalized.

Similarly, the pressure is controlled to be uniform in the regions below a gas supply/exhaust structure 280a, a gas supply/exhaust structure 280b and a gas supply/exhaust structure 280c. Thereby, process conditions of the gas supply/exhaust structure 280a, the gas supply/exhaust structure 280b and the gas supply/exhaust structure 280c can be equalized. As a result, characteristics of layers formed when passing through the respective below regions can be equalized.

[Susceptor]

The susceptor 220 that acts as the substrate support table and is configured to be rotatable with the center of a rotating shaft placed in the center of the reaction vessel 203 is installed below gas supply holes, i.e., in the middle of a bottom side in the reaction vessel 203. The susceptor 220 is formed of a non-metal material such as aluminum nitride (AlN), ceramic or quartz so as to be able to reduce metal contamination of the wafer 200. Further, the susceptor 220 is electrically insulated from the reaction vessel 203.

The susceptor 220 is configured to arrange and support a plurality of wafers 200 (five wafers in the present embodiment) on the same plane or in a same circumferential shape in the reaction vessel 203. Here, the same plane is not limited to completely the same plane, and may be arranged such that the plurality of wafers 200 do not overlap each other when the susceptor 220 is viewed from the top. Further, the susceptor 220 is configured to arrange and dispose the plurality of wafers 200 in the rotational direction.

Wafer placement units 221 are installed at positions at which the wafers 200 are supported on the surface of the susceptor 220. The wafer placement units 221, the number of which is equal to the number of wafers 200 to be processed, are disposed at regular intervals (for instance, intervals of 72 degrees) at positions on the concentric circle from the center of the susceptor 220.

Each of the wafer placement units 221 is, for instance, a circular shape when viewed from the top of the susceptor 220, and a recessed shape when viewed from the side. A diameter of the wafer placement unit 221 is preferably configured to be slightly larger than that of the wafer 200. The wafer 200 is placed in the wafer placement unit 221, and thereby the wafer 200 can be easily positioned. Furthermore, the wafer 200 can be inhibited from being improperly positioned, for instance from protruding from the susceptor 220, by a centrifugal force involved in rotation of the susceptor 220.

The susceptor 220 is provided with an elevation mechanism 222 elevating the susceptor 220. The elevation mechanism 222 is connected to a controller 400 to be described below, and the susceptor 220 is elevated according to an instruction of the controller 400. Each of the wafer placement units 221 of the susceptor 220 is provided with a plurality of through-holes 223. Wafer elevation pins 224 are provided in the respective through-holes 223. When the wafer 200 is placed, the susceptor 220 moves to a conveyance position to bring lower ends of the wafer elevation pins 224 into contact with a bottom surface of the reaction vessel 203. The wafer elevation pins 224 brought into contact moves up to a position higher than a surface of the wafer placement unit 221. In this way, the wafer 200 moves up from the surface of the wafer placement unit 221, and the wafer is placed.

A shaft of the susceptor 220 is provided with a rotary mechanism 225 rotating the susceptor 220. A rotary shaft of the rotary mechanism 225 is configured to be connected to the susceptor 220 so as to be able to rotate the susceptor 220 by operating the rotary mechanism 225. Further, the susceptor 220 is configured to be rotated, and thereby the plurality of wafer placement units 221 are rotated en bloc. The rotary mechanism 225 is also called a rotation unit.

The controller 400 to be described below is connected to the rotary mechanism 225 via a coupler 226. The coupler 226 is configured, for instance, as a slip ring mechanism that provides electrical connection between a rotary side and a stationary side using a metal brush. This prevents the rotation of the susceptor 220 from being obstructed. The controller 400 is configured to control an electrical conduction state to the rotary mechanism 225 so as to rotate the susceptor 220 at a given speed for a given time.

[Heating Unit]

A heater 228 acting as a heating unit is configured to be integrally embedded in the susceptor 220 so as to be able to heat the wafer 200. When power is supplied to the heater 228, a surface of the wafer 200 is configured to be heatable to a given temperature (for instance, room temperature to about 1,000° C.). Alternatively, a plurality of heaters 228 (for instance, five heaters) may be provided on the same plane so as to individually heat the respective wafers placed on the susceptor 220.

The susceptor 220 is provided with a temperature sensor 227. A power regulator 230, a heater power supply 231 and a temperature regulator 232 are electrically connected to the heaters 228 and the temperature sensor 227 via a power supply cable 229. The electrical conduction to the heaters 228 is configured to be controlled based on information about a temperature detected by the temperature sensor 227.

[Gas Supply/Exhaust Structure]

The gas supply/exhaust structure 240, gas supply/exhaust structure 280 and gas supply structure 320 are radially provided radially when viewed from the middle of a ceiling that is an upper side of the process chamber.

The gas supply/exhaust structure 240 has the first gas supply structure 241 supplying a first gas, and is provided with the gas exhaust structure 243 so as to surround it. The gas supply/exhaust structure 280 has the second gas supply structure 281 supplying a second gas, and is provided with the gas exhaust structure 283 so as to surround it. The gas supply structure 320 has the third gas supply structure 321 supplying an inert gas.

The first gas supply structure 241, the second gas supply structure 281 and the third gas supply structure 320 are shaped of, for instance, a pedestal. A susceptor radial width of each structure is at least set to be larger than a diameter of the wafer 200, and thereby a structure in which a gas can be supplied to the entire surface of the wafer 200 passing through a region below each gas supply hole is formed.

The first gas exhaust channel 246 is provided to surround the first gas supply structure 241 in a horizontal direction, and evaculates the first gas that is not attached to the surface of the wafer 200 or the susceptor 220 and the inert gas that is supplied by the neighboring third gas supply structures 320. With this configuration, it is possible to prevent mixture with the second gas supplied to the neighboring spaces.

The first gas exhaust channel 246 is provided between the neighboring third gas supply structures 320 as well as at a center side or an outer circumference side of the process chamber, for instance, when viewed from the gas supply structure.

The first gas exhaust channel 246 is provided at the center side of the process chamber, and thereby a large quantity of gas is prevented from being introduced into the center of the process chamber or the neighboring gas supply regions via the center of the process chamber. Here, the process chamber center side of the first gas exhaust channel 246 is referred to as an inner circumference gas migration inhibition portion.

Further, the first gas exhaust channel 246 is provided at the outer circumference side of the process chamber, and thereby a large quantity of gas is prevented from being introduced in a wall direction of the process chamber. Here, the process chamber outer circumference side of the first gas exhaust channel 246 is referred to as an outer circumference gas migration inhibition portion.

The second gas exhaust channel 286 is provided to surround the second gas supply structure 281 in a horizontal direction, and evaculates the second gas that is not attached to the surface of the wafer 200 or the susceptor 220 and the inert gas that is supplied by the neighboring third gas supply structures 320. With this configuration, it is possible to prevent mixture with the first gas supplied to the neighboring spaces.

The second gas exhaust channel 286 is provided between the neighboring third gas supply structures 320 as well as at a center side or an outer circumference side of the process chamber, for instance, when viewed from the gas supply structure.

The second gas exhaust channel 286 is provided at the center side of the process chamber, and thereby a large quantity of gas is prevented from being introduced into the center of the process chamber or the neighboring gas supply regions via the center of the process chamber. Here, the process chamber center side of the second gas exhaust channel 286 is referred to as an inner circumference gas migration inhibition portion.

Further, the second gas exhaust channel 286 is provided at the outer circumference side of the process chamber, and thereby a large quantity of gas is prevented from being introduced in a wall direction of the process chamber. Here, the process chamber outer circumference side of the second gas exhaust channel 286 is referred to as an outer circumference gas migration inhibition portion.

The inner circumference gas migration inhibition portion of the first gas exhaust channel 246 and the inner circumference gas migration inhibition portion of the second gas exhaust channel 286 may be referred to collectively as an inner circumference gas migration inhibition portion. Further, the outer circumference gas migration inhibition portion of the first gas exhaust channel 246 and the outer circumference gas migration inhibition portion of the second gas exhaust channel 286 may be referred to collectively as an outer circumference gas migration inhibition portion.

When arrangement of the gas supply/exhaust structure 240, the gas supply/exhaust structure 280 and the gas supply structure 320 is viewed from the side in the rotational direction, a plurality of combinations, in each of which the first gas exhaust channel 246, the first gas supply structure 241, the first gas exhaust channel 246, the third gas supply structure 320, the second gas exhaust channel 286, the second gas supply structure 281, the second gas exhaust channel 286 and the third gas supply structure 320 are combined in that order, are disposed. By disposing the plurality of combinations, the number of layers per one rotation is increased to enhance process throughput.

In the present embodiment, the description has been made using the three gas supply/exhaust structures 240 of the gas supply/exhaust structure 240a to the gas supply/exhaust structure 240c. However, the present embodiment is not limited thereto, and four or more gas supply/exhaust structures may be used.

Further, in the present embodiment, the description has been made using the three gas supply/exhaust structures 280 that are the gas supply/exhaust structure 280a to the gas supply/exhaust structure 280c. However, the present embodiment is not limited thereto, and four or more gas supply/exhaust structures may be used.

Furthermore, in the present embodiment, the description has been made using the six gas supply/exhaust structures 320 that are the gas supply structure 320a to the gas supply structure 320f. However, the present embodiment is not limited thereto, and seven or more gas supply structures may be used.

Subsequently, a specific structure of the gas supply/exhaust structure 240 will be described using FIG. 6. FIG. 6 is a view illustrating a cross section taken along line D-D′ of FIG. 4 when viewed in a diagonal view direction. Note that parentheses of FIG. 6 indicate a symbol of the gas supply/exhaust structure 280 to be described below.

The gas supply/exhaust structure 240 has the first gas supply structure 241 supplying a first gas. A supply pipe 242 is connected to an upper side of the first gas supply structure 241. The first gas exhaust structure 243 is provided to cover the first gas supply structure 241. The supply pipe 242 is connected to a downstream supply pipe 251 of FIG. 8. To be specific, a supply pipe 242a is connected to a downstream supply pipe 251a, a supply pipe 242b is connected to a downstream supply pipe 251b, and a supply pipe 242c is connected to a downstream supply pipe 251c.

An exhaust pipe 244 is connected to the first gas exhaust structure 243. The exhaust pipe 244 is connected to an upstream side exhaust pipe 271 of FIG. 9. To be specific, an exhaust pipe 244a is connected to an upstream side exhaust pipe 271a, an exhaust pipe 244b is connected to an upstream side exhaust pipe 271b, and an exhaust pipe 244c is connected to an upstream side exhaust pipe 271c.

The gas supplied through the supply pipe 242 is supplied to the process chamber via the gas supply channel 245 that is an inner space of the first gas supply structure 241. A space is provided between the gas supply structure 241 and the gas exhaust structure 243, and is used as the first gas exhaust channel 246 through which the gas exhausted from the process chamber flows.

Subsequently, a specific structure of the gas supply/exhaust structure 280 will be described using FIG. 6. The gas supply/exhaust structure 280 has the second gas supply structure 281 supplying a second gas. The second gas exhaust structure 283 is provided to cover the second gas supply structure 281. Supply pipes 282 are connected to the second gas supply structure 281. To be specific, a supply pipe 282a is connected to a downstream supply pipe 291a, a supply pipe 282b is connected to a downstream supply pipe 291b, and a supply pipe 282c is connected to a downstream supply pipe 291c.

An exhaust pipe 284 is connected to the second gas exhaust structure 283. The exhaust pipe 284 is connected to an upstream side exhaust pipe 311 of FIG. 11. To be specific, an exhaust pipe 284a is connected to an upstream side exhaust pipe 311a, an exhaust pipe 284b is connected to an upstream side exhaust pipe 311b, and an exhaust pipe 284c is connected to an upstream side exhaust pipe 311c.

The gas supplied through the supply pipes 282 is supplied to the process chamber via the gas supply channel 285 that is an inner space of the gas supply structure 281. A space is provided between the gas supply structure 281 and the gas exhaust structure 283, and is used as the second gas exhaust channel 286 through which the gas exhausted from the process chamber flows.

Subsequently, a specific structure of the gas supply structure 320 will be described using FIG. 7. The gas supply structure 320 includes a third gas supply structure 321 supplying a third gas. Supply pipes 322 are connected to the gas supply structure 320.

The supply pipes 322 are connected to downstream supply pipes 331 of FIG. 12. To be specific, a supply pipe 322a is connected to a downstream supply pipe 331a, a supply pipe 322b is connected to a downstream supply pipe 331b, a supply pipe 322c is connected to a downstream supply pipe 331c, a supply pipe 322d is connected to a downstream supply pipe 331d, a supply pipe 322e is connected to a downstream supply pipe 331e, and a supply pipe 322f is connected to a downstream supply pipe 331f. The gas supplied through the supply pipes 322 is supplied to the process chamber via a gas supply channel 323 that is an inner space of the third gas supply structure 321.

[Gas Supply Unit and Gas Exhaust Unit]

Subsequently, a gas supply unit that supplies a gas to each of the gas supply/exhaust structure 240, the gas supply/exhaust structure 280 and the gas supply structure 320 will be described.

[First Gas Supply Unit]

The first gas supply unit 250 will be described using FIG. 8. The first gas supply unit 250 functions to supply the gas to the gas supply/exhaust structure 240. This will be described below in detail.

The first gas supply unit 250 includes a plurality of downstream supply pipes 251. The downstream supply pipes 251 are connected to the respective gas supply/exhaust structures 240. To be specific, a downstream supply pipe 251a is connected to a supply pipe 242a, a downstream supply pipe 251b is connected to a supply pipe 242b, and a downstream supply pipe 251c is connected to a supply pipe 242c.

The plurality of downstream supply pipes 251 are joined at an upstream confluence part 252. A supply pipe 253 is connected upstream from the confluence part. A first gas source 254 is connected to an upstream end of the supply pipe 253. A mass flow controller (MFC) 255 acting as a flow rate regulator (flow rate regulation unit) and an opening/closing valve 256 are provided from upstream between the first gas source 254 and the confluence part.

A gas containing a first element (hereinafter referred to as “first element-containing gas” or “first gas”) is supplied to the gas supply/exhaust structure 240 through the upstream supply pipe 253 via the mass flow controller 255 and the valve 256.

The first element-containing gas is a source gas, that is, one of process gases. The first element is, for instance, titanium (Ti). That is, the first element-containing gas is, for instance, a titanium-containing gas. The first element-containing gas may be any one of a solid, a liquid and a gas at room temperature under normal pressure. When the first element-containing gas is the liquid at room temperature under normal pressure, a vaporizer (not shown) may be provided between the first gas source 254 and the mass flow controller 255. Here, the description will be made as the gas.

A downstream end of a first inert gas supply pipe 257 is connected downstream relative to the valve 256 of the upstream supply pipe 253. An inert gas source 258, a mass flow controller (MFC) 259 that is a flow rate controller (flow rate control unit) and a valve 260 that is an opening/closing valve are provided for the first inert gas supply pipe 257 in turn from an upstream direction.

Here, the inert gas is, for instance, nitrogen (N₂) gas. As the inert gas, a rare gas such as helium (He) gas, neon (Ne) gas or argon (Ar) gas may be used in addition to the N₂ gas.

The downstream supply pipe 251, the upstream supply pipe 253, the MFC 255 and the opening/closing valve 256 are mainly referred to as the first gas supply unit 250.

Further, a first inert gas supply system is mainly configured by the first inert gas supply pipe 257, the mass flow controller 259 and the valve 260. The inert gas source 258, the downstream supply pipe 251 and the upstream supply pipe 253 may be thought to be included in a first inert gas supply unit.

Further, the first gas source 254, the first inert gas supply unit and the gas supply/exhaust structure 240 may be thought to be included in the first gas supply unit.

[First Gas Exhaust Unit]

Subsequently, the first gas exhaust unit 270 will be described using FIG. 9. The first gas exhaust unit 270 includes the upstream side exhaust pipes 271 connected to the exhaust pipes 244. The upstream side exhaust pipes 271 are connected to the respective exhaust pipes 244. To be specific, the exhaust pipe 244a is connected to the exhaust pipe 271a, the exhaust pipe 244b is connected to the exhaust pipe 271b, and the exhaust pipe 244c is connected to the exhaust pipe 271c.

The plurality of exhaust pipes 271 are jointed at a confluence part 272. A downstream side exhaust pipe 273 is connected downstream from the confluence part 272. A valve 274 acing as an opening/closing valve, an auto pressure controller (APC) valve 275 acting as a pressure regulator (pressure regulation unit) and a pump 276 are disposed at the downstream side exhaust pipe 273 from upstream.

Each of the upstream side exhaust pipes 271 is provided with a pressure detector 277. The pressure detector is used, for instance, as a flow rate detector. The upstream side exhaust pipe 271a is provided with a pressure detector 277a, the upstream side exhaust pipe 271b is provided with a pressure detector 277b, and the upstream side exhaust pipe 271c is provided with a pressure detector 277c. The plurality of pressure detectors 277 provided for the first gas exhaust unit are referred to collectively as a first pressure detection unit. The pressure detectors 277 are connected to the controller 400. A flow rate of each upstream side exhaust pipe 271 is detected by each pressure detector 277.

The APC valve 275 is an opening/closing valve that can open/close a valve to perform or stop vacuum exhaust in the process room 201 and is also configured to be able to adjust a degree of valve opening to regulate pressure in the process room 201. The exhaust unit is mainly configured by the first gas exhaust channel 246, the upstream side exhaust pipe 271, the downstream side exhaust pipe 273, the valve 274 and the APC valve 275.

When the first element-containing gas is used as the source gas, the first gas supply/exhaust structure may be referred to as a source gas supply/exhaust structure, the first gas supply unit may be referred to as a source gas supply unit, and the first gas exhaust unit may be referred to as a source gas exhaust unit. Further, in other components, the first gas may be replaced with the source gas.

[Second Gas Supply Unit]

The second gas supply unit 290 will be described using FIG. 10. The second gas supply unit 290 functions to supply a gas to the gas supply/exhaust structure 280. This will be described below in detail.

The second gas supply unit 290 includes a plurality of downstream supply pipes 291. The downstream supply pipes 291 are connected to the respective gas supply/exhaust structure 280. To be specific, the downstream supply pipe 291a is connected to the supply pipe 282a, the downstream supply pipe 291b is connected to the supply pipe 282b, and the downstream supply pipe 291c is connected to the supply pipe 282c.

The downstream supply pipes 291 are joined at a confluence part 292, and are connected to an upstream supply pipe 293. A second gas source 294 is connected to an upstream end of the supply pipe 293. A mass flow controller (MFC) 295 acting as a flow rate regulator (flow rate regulation unit), an opening/closing valve 296 and a plasma generation unit 297 are provided from upstream between the second gas source 294 and the confluence part.

A gas containing a second element (hereinafter referred to as “second element-containing gas” or “second gas”) is supplied to the gas supply/exhaust structure 280 through the upstream supply pipe 293 via the mass flow controller 295 and the valve 296.

The second element-containing gas is a reactive gas, that is, one of process gases. The second element is, for instance, nitrogen (N). That is, the second element-containing gas is, for instance, a nitrogen-containing gas.

A downstream end of a second inert gas supply pipe 298 is connected downstream relative to the valve 296 of the upstream supply pipe 293. An inert gas source 299, a mass flow controller (MFC) 300 that is a flow rate controller (flow rate control unit) and a valve 301 that is an opening/closing valve are provided for the second inert gas supply pipe 298 in turn from an upstream direction.

Here, the inert gas is, for instance, nitrogen (N₂) gas. As the inert gas, a rare gas such as helium (He) gas, neon (Ne) gas or argon (Ar) gas may be used in addition to the N₂ gas.

The downstream supply pipe 291, the upstream supply pipe 293, the MFC 295 and the opening/closing valve 296 are mainly referred to as the second gas supply unit 290.

Further, a second inert gas supply system is mainly configured by the second inert gas supply pipe 298, the mass flow controller 300 and the valve 301. The inert gas source 299, the downstream supply pipe 291 and the upstream supply pipe 293 may be thought to be included in a second inert gas supply unit.

Further, the second gas source 294, the plasma generation unit 297, the second inert gas supply unit and the gas supply/exhaust structure 280 may be thought to be included in the second gas supply unit.

[Second Gas Exhaust Unit]

Subsequently, the second gas exhaust unit 310 will be described using FIG. 11. The second gas exhaust unit 310 includes the upstream side exhaust pipes 311 connected to the exhaust pipes 284. The upstream side exhaust pipes 311 are connected to the respective exhaust pipes 284. To be specific, the exhaust pipe 284a is connected to the exhaust pipe 311a, the exhaust pipe 284b is connected to the exhaust pipe 311b, and the exhaust pipe 284c is connected to the exhaust pipe 311c.

The plurality of exhaust pipes 311 are jointed at a confluence part 312. A downstream side exhaust pipe 313 is connected downstream from the confluence part 312. A valve 314 acing as an opening/closing valve, an auto pressure controller (APC) valve 315 acting as a pressure regulator (pressure regulation unit) and a pump 316 are disposed at the downstream side exhaust pipe 313 from upstream.

Each of the upstream side exhaust pipes 311 is provided with a pressure detector. The pressure detector is used, for instance, as a flow rate detector. The pressure detectors 317 are installed on the respective upstream side exhaust pipes 311. A pressure detector 317a is installed on the upstream side exhaust pipe 311a, a pressure detector 317b is installed on the upstream side exhaust pipe 311b, and a pressure detector 317c is installed on the upstream side exhaust pipe 311c. The plurality of pressure detectors 317 provided for the second gas exhaust unit are referred to collectively as a second pressure detection unit. The pressure detectors are connected to the controller 400. A flow rate of each upstream side exhaust pipe 311 is detected by each pressure detector 317. A detecting method will be described below.

The APC valve 315 is an opening/closing valve that can open/close a valve to perform or stop vacuum exhaust in the process room 201 and is also configured to be able to adjust a degree of valve opening to regulate a pressure in the process room 201. The exhaust unit is mainly configured by the second gas exhaust channel 286, the upstream side exhaust pipe 311, the downstream side exhaust pipe 313, the valve 314 and the APC valve 315. The flow rate of each upstream side exhaust pipe is detected by each pressure detector 317. A detecting method will be described below.

When the second element-containing gas is used as the reactive gas, the second gas supply/exhaust structure may be referred to as a reactive gas supply/exhaust structure, the second gas supply unit may be referred to as a reactive gas supply unit, and the second gas exhaust unit may be referred to as a reactive gas exhaust unit. Further, in other components, the second gas may be replaced with the reactive gas.

[Third Gas Supply Unit]

The third gas supply unit 330 will be described using FIG. 12. The third gas supply unit 330 functions to supply a gas to the gas supply structure 320. This will be described below in detail.

The third gas supply unit 330 includes a plurality of downstream supply pipes 331. The downstream supply pipes 331 are connected to the respective gas supply structure 320. To be specific, the downstream supply pipe 331a is connected to the supply pipe 322a, the downstream supply pipe 331b is connected to the supply pipe 322b, the downstream supply pipe 331c is connected to the supply pipe 322c, the downstream supply pipe 331d is connected to the supply pipe 322d, the downstream supply pipe 331e is connected to the supply pipe 322e, and the downstream supply pipe 331f is connected to the supply pipe 322f.

The downstream supply pipes 331 are joined at a confluence part 332, and are connected to an upstream supply pipe 333. A third gas source 334 is connected to an upstream end of the supply pipe 333. A mass flow controller (MFC) 335 acting as a flow rate regulator (flow rate regulation unit) and an opening/closing valve 336 are provided from upstream between the third gas source 334 and the confluence part.

A gas containing a third element (hereinafter referred to as “third element-containing gas” or “third gas”) is supplied to the gas supply structure 320 through the upstream supply pipe 333 via the mass flow controller 335 and the valve 336.

Here, an inert gas is mainly used as the third gas. The inert gas is, for instance, nitrogen (N₂) gas. As the inert gas, a rare gas such as helium (He) gas, neon (Ne) gas or argon (Ar) gas may be used in addition to the N₂ gas.

The downstream supply pipes 331, the upstream supply pipe 333, the mass flow controller 335 and the valve 336 are mainly referred to as the third gas supply unit. The third gas source 334 may be thought to be included in the third gas supply unit.

When the third element-containing gas is used as the inert gas, the third gas supply structure may be referred to as an inert gas supply structure, and the third gas supply unit may be referred to as an inert gas supply unit. Further, in other components, the third gas may be replaced with the inert gas.

[Controller]

The substrate processing apparatus 10 includes the controller (control unit) 400 that controls an operation of each unit of the substrate processing apparatus 10. The controller 400 includes at least an operation unit 401 and a storage unit 402. The controller 400 is connected to each of the aforementioned components, calls a program or a recipe from the storage unit 402 according to an instruction of the controller or a user, and controls an operation of each component according to contents of the program or the recipe. The controller 400 may be configured as a dedicated computer or a general-purpose computer. For example, an external storage device 403 in which the aforementioned program is stored (for instance, a magnetic tape, a magnetic disk such as a flexible disk or a hard disk, an optical disk such as a compact disc (CD) or a digital versatile disc (DVD), a magneto-optical (MO) disc or a semiconductor memory such as a universal serial bus (USB) memory (USB flash drive) or a memory card) is prepared, and the program is installed in the general-purpose computer using the external storage device 403. Thereby, the controller 400 according to the present embodiment may be configured. Further, a means for supplying the program to the computer is not limited to supplying the program via the external storage device 403. For example, the program may be supplied using a telecommunication means such as the Internet or a private line without the external storage device 403. The storage unit 402 or the external storage device 403 is configured as a computer readable recording medium. Hereinafter, these are referred to collectively simply as a recording medium. The term recording medium used herein may include only the storage unit 402, only the external storage device 403, or both of these.

[Process of Processing Substrate]

Subsequently, as one process of a method of manufacturing a semiconductor device according to the present embodiment, a process of processing a substrate using the aforementioned substrate processing apparatus having the process chamber 202 will be described.

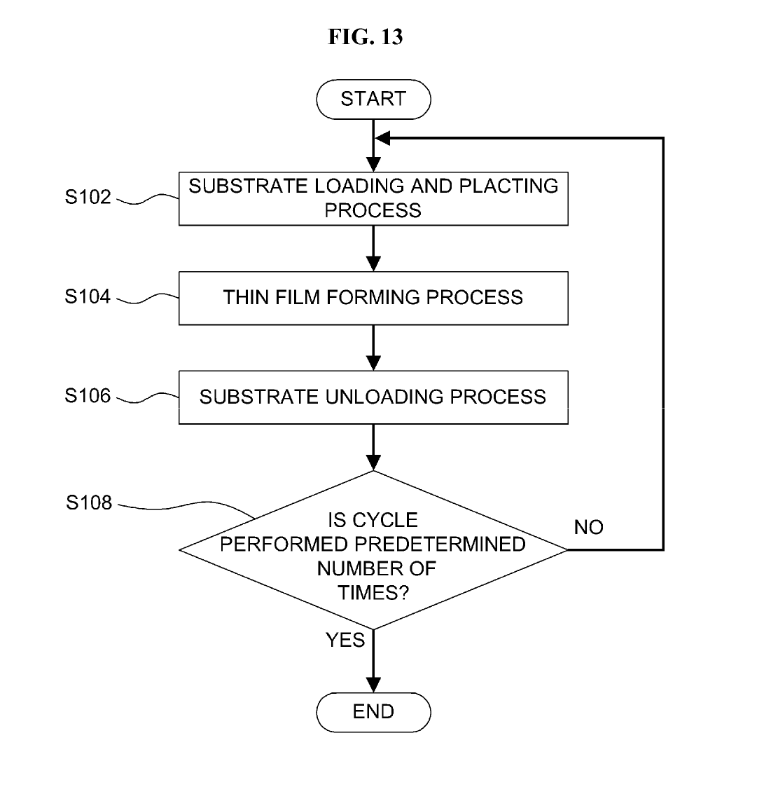

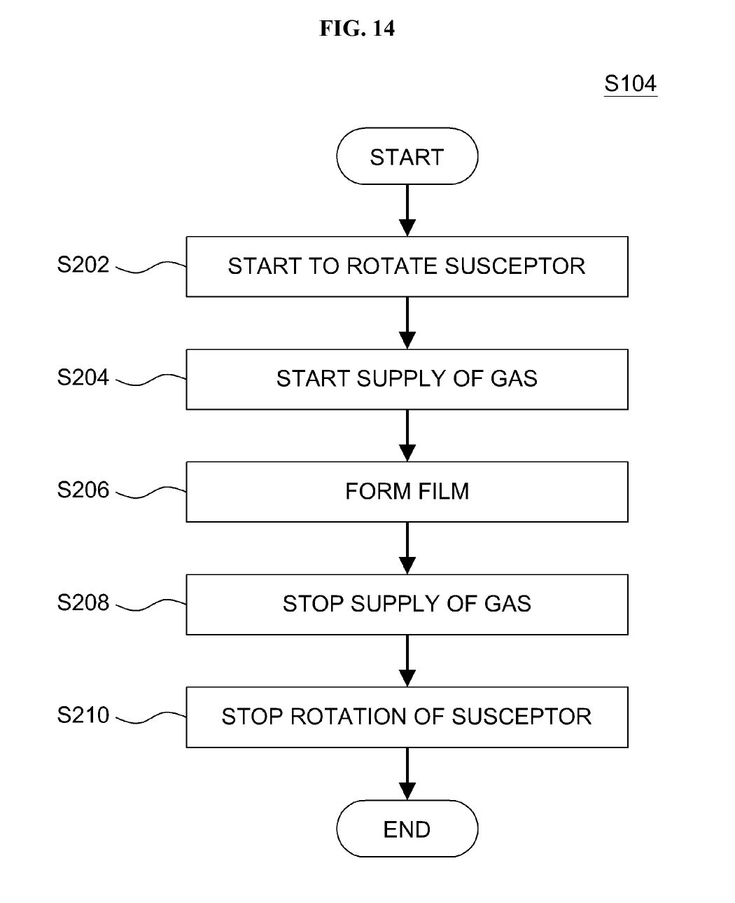

First, an outline of the process of processing the substrate will be described using FIGS. 13 and 14. FIG. 13 is a flowchart illustrating the process of processing the substrate. FIG. 14 is a flowchart of a film forming process according to the present embodiment. In the following description, the operation of each constituent unit of the process chamber 202 of the substrate processing apparatus 10 is controlled by the controller 400.

Here, an example in which a titanium nitride film is formed on the wafer 200 as a thin film using a TiCl₄ gas as a first element-containing gas and using an ammonia (NH₃) gas as a second element-containing gas will be described. Further, a given film may be formed, for instance, on the wafer 200 in advance. Further, a given pattern may be formed on the wafer 200 or the given film.

[Substrate Loading and Placing Process S102]

For example, the FOUP 100 in which maximum 25 wafers are accommodated is conveyed by the in-process conveyance device, and is placed on the load port 105. The cap 100a of the FOUP 100 is removed by the FOUP opener 108, and a substrate gate of the FOUP 100 is opened. The second substrate transfer machine 124 picks up the wafer 200 from the FOUP 100, and place it on the notch alignment device 106. The notch alignment device 106 positions the wafer 200. The second substrate transfer machine 124 loads the wafer 200 into the spare chamber 122 under atmospheric pressure from the notch alignment device 106. The gate valve 128 is closed, and the interior of the spare chamber 122 is exhausted to a negative pressure by an exhaust system (not shown).

The susceptor 220 is displaced to and maintained at a conveyance position of the wafer 200, namely a substrate placement position in the process chamber 202. In the present embodiment, the susceptor 220 is caused to move down. The downward movement causes the wafer elevation pins 224 to move up in the through-holes 223 of the susceptor 220. As a result, the wafer elevation pins 224 are kept protruding from the surface of the susceptor 220 by a given height only. Subsequently, a given gate valve is opened, and a given number (e.g., five) of wafers (process substrates) 200 are loaded into the process room 201 using a vacuum conveyance robot 112. Then, the wafers 200 are placed around the rotary shaft of the susceptor 220 in a rotational direction of the susceptor 220 such that the wafers 200 do not overlap. Thereby the wafers 200 are supported on the wafer elevation pins 224 protruding from the surface of the susceptor 220 in a horizontal posture.

When the wafer 200 is loaded into the process room 201, the first conveyance robot 112 is retreated outside the process chamber 202, the predetermined gate valve is closed to seal the interior of the reaction vessel 203. Afterwards, the susceptor 220 is displaced to and maintained at the substrate processing position. In the present embodiment, the susceptor 220 is caused to move up. The upward movement of the susceptor 220 causes the wafer 200 to be placed on each wafer placement unit 221 provided for the susceptor 220.

When the wafer 200 is loaded into the process room 201, a N₂ gas used as an inert gas is preferably supplied into the process room 201 by the third gas supply unit while the interior of the process room 201 is exhausted by the first gas exhaust unit 270 and the second gas exhaust unit 310. That is, in a state in which the interior of the process room 201 is exhausted by operating the pump 276 and the pump 316 and opening the APC valve 275 and the APC valve 315, the N₂ gas is preferably supplied into the process room 201 by at least opening the valve 274 and the valve 314. Thereby, it is possible to inhibit particles from intruding into the process room 201 or from being attached onto the wafer 200. Further, the pump 276 and the pump 316 are at least kept operated normally until the substrate loading and placing process S102 to a substrate unloading process S106 to be described below are completed.

When the wafer 200 is placed on the susceptor 220, power is supplied to the heater 228 embedded in the susceptor 220, and the surface of the wafer 200 is controlled to reach a predetermined temperature. The temperature of the wafer 200 is for instance room temperature or more and 700° C. or less, and preferably room temperature or more and 500° C. or less. At this time, a temperature of the heater 228 is adjusted by controlling an electrical conduction to the heater 228 based on information about a temperature detected by the temperature sensor 227.

When the surface temperature of the wafer 200 is heated to 750° C. or more in a process of heating the wafer 200 formed of silicon, diffusion of impurities may occur in a source or drain region formed on the surface of the wafer 200. Accordingly, circuit characteristics may be deteriorated, and performance of a semiconductor device may be reduced. By restricting the temperature of the wafer 200 as described above, it is possible to inhibit the diffusion of the impurities into the source or drain region formed on the surface of the wafer 200, the deterioration of the circuit characteristics, and the reduction in the performance of the semiconductor device.

[Thin Film Forming Process S104]

Next, a thin film forming process S104 is performed. Here, a basic flow of the thin film forming process S104 will be described, and characteristic portions of the present embodiment will be described below in detail.

In the thin film forming process S104, a TiCl₄ gas is supplied by a first gas supply structure 241a, a first gas supply structure 241b and a first gas supply structure 241c, and an ammonia gas of a plasma state is supplied by a second gas supply structure 281a, a second gas supply structure 281b and a second gas supply structure 281c. Accordingly, a titanium nitride (TiN) film is formed on the wafer 200.

In the thin film forming process S104, the interior of the process room 201 is continuously exhausted by the first gas exhaust unit 270 and the second gas exhaust unit 310 even after the substrate loading and placing process S102. In conjunction with this, the N₂ gas used as the inert gas are supplied by a third gas supply structure 321a, a third gas supply structure 321b, a third gas supply structure 321c, a third gas supply structure 321d, a third gas supply structure 321e and a third gas supply structure 321f.

[Start to Rotate Susceptor S202]

Subsequently, details of the thin film forming process S104 will be described using FIG. 14. First, when the wafers 200 are placed on the respective wafer placement units 221, the susceptor 220 starts to be rotated by the rotary mechanism 225. At this time, a speed of rotation of the susceptor 220 is controlled by the controller 400. The rotation speed of the susceptor 220 is for instance one rotation per minute or more and 100 rotations per minute or less. In detail, the rotation speed is for instance 60 rotations per minute. By rotating the susceptor 220, the surface of the susceptor 220 and the wafer 200 start to move in regions below the gas supply/exhaust structure 240 and the gas supply/exhaust structure 280. Together with the rotation start, the pressure detector 277a, the pressure detector 277b and the pressure detector 277c are operated.

[Start Supply of Gas S204]

When the wafer 200 is heated to reach a desired temperature and the susceptor 220 reaches a desired rotation speed, the TiCl₄ gas starts to be supplied by the gas supply structure 241a, the gas supply structure 241b and the gas supply structure 241c. In conjunction with this, the ammonia gas of the plasma state is supplied by the gas supply structure 281a, the gas supply structure 281b and the gas supply structure 281c.

At this time, the mass flow controller 255 is adjusted such that a flow rate of the TiCl₄ gas reaches a predetermined flow rate. Further, the flow rate of supply of the TiCl₄ gas is for instance 100 sccm or more and 5,000 sccm or less. Together with the TiCl₄ gas, the N₂ gas may be supplied as a carrier gas.

The mass flow controller 295 is adjusted such that a flow rate of the ammonia gas becomes a predetermined flow rate. The flow rate of the supplied ammonia gas is for instance 100 sccm or more and 5,000 sccm or less. Together with the ammonia gas, the N₂ gas may be supplied as the carrier gas.

Further, the degrees of opening of the APC valve 275 and the APC valve 315 are properly adjusted, and thereby a pressure in the process room 201 including the region below each gas supply/exhaust structure is set to a predetermined pressure.

A titanium-containing layer having a predetermined thickness starts to be formed on the surface of the wafer 200 or the susceptor from the process of starting the supply of the gas S204.

[Film Forming Process S206]

Next, a film forming process to be described below is performed by rotating the susceptor 220 a predetermined number of times. At this time, since the surfaces of the wafer 200 and the susceptor 220 are exposed to the gas, a film is formed on the wafer 200, and simultaneously a film is formed on the surface of the susceptor 220.

Further, a flow of the gas or atmosphere is formed in the film forming process as follows. In the region below the first gas supply/exhaust structure 240a, the first gas supplied by the first gas supply structure 241a forms a titanium-containing layer on the wafer 200, and then is exhausted by a first gas exhaust structure 243a. This is true of the first gas supply/exhaust structure 240b and the first gas supply/exhaust structure 240c.

Further, in the region below the second gas supply/exhaust structure 280a, the second gas supplied by the second gas supply structure 281a reacts with the titanium-containing layer on the wafer 200, and then is exhausted by a second gas exhaust structure 283a. This is true to the second gas supply/exhaust structure 280b and the second gas supply/exhaust structure 280c.

Further, the third gas supplied by the third gas supply structure 320a extrudes (removes) a remaining gas on the wafer 200 passing through the region below the third gas supply structure 320a, and then is exhausted along with the remaining gas component by the first gas exhaust structure 243a or the second gas exhaust structure 283a. This is same to the third gas supply structure 320b and the third gas supply structure 320c.

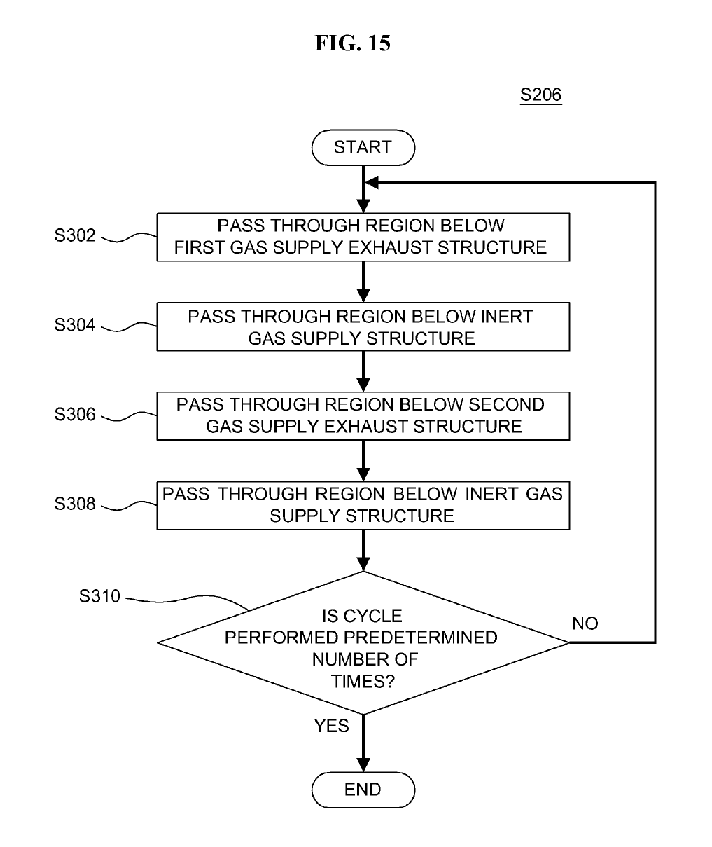

Here, details of the film forming process S206 will be described using FIG. 15.

[Passing Through Region Below First Gas Supply/Exhaust Structure (S302)]

When the wafer 200 passes through the region below the first gas supply/exhaust structure 240, the TiCl₄ gas is supplied to the wafer 200. The TiCl₄ gas comes into contact with the surface of the wafer 200, and thereby a titanium-containing layer is formed as a “first element-containing layer.” The first gas supplied onto the wafer 200 is exhausted via the gas exhaust structure 243, and an exhausted flow rate is detected by the pressure detector 277.

The titanium-containing layer is formed at a predetermined thickness and with a predetermined distribution, for instance, according to a pressure of the region blow the first gas supply/exhaust structure 240, a pressure in the process room 201, a flow rate of the TiCl₄ gas, a temperature of the susceptor 220, a time required to pass through the region below the first gas supply structure (processing time in the region below the first gas supply structure), and so on.

[Passing Through Region Below Inert Gas Supply Structure (S304)]

Next, after the wafer 200 passes through the region below the first gas supply/exhaust structure 240, the wafer 200 moves in a rotational direction R of the susceptor 220 and to the region below the inert gas supply structure 320. When the wafer 200 passes through the region below the inert gas supply structure 320, a titanium component not bonded to the wafer 200 in the region below of the first gas supply/exhaust structure 240 is removed from the wafer 200.

[Passing Through Region Below Second Gas Supply/Exhaust Structure (S306)]

Next, after the wafer 200 passes through the region below the inert gas supply structure 320, the wafer 200 moves in the rotational direction R of the susceptor 220 and to the region below the second gas supply/exhaust structure 280. When the wafer 200 passes through the region below the second gas supply/exhaust structure 280, the titanium-containing layer and the ammonia gas react to form a titanium nitride layer in the region below the second gas supply/exhaust structure 280. The second gas supplied onto the wafer 200 is exhausted via the second gas exhaust structure 283, and an exhausted flow rate is detected by the pressure detector 317.

[Passing Through Region Below Inert Gas Supply Structure (S308)]

Next, after the wafer 200 passes through the region below the second gas supply/exhaust structure 280, the wafer 200 moves in the rotational direction R of the susceptor 220 and to the region below the inert gas supply structure 320. When the wafer 200 passes through the region below the inert gas supply structure 320, a nitrogen component failing to react with the titanium-containing layer of the wafer 200 in the region below the second gas supply/exhaust structure 280 is removed from the wafer 200 by the inert gas.

[Decision S310]

In the meantime, the controller 400 decides whether to perform one cycle a predetermined number of times. In detail, the controller 400 counts the number of revolutions of the susceptor 220.

When one cycle is not performed a predetermined number of times (No in S310), the rotation of the susceptor 220 continues to repeat the cycle of the passing through the region below the first gas supply/exhaust structure (S302), the passing through the region below the inert gas supply structure (S304), the passing through the region below the second gas supply/exhaust structure (S306) and the passing through the region below the inert gas supply structure (S308). When one cycle is performed a predetermined number of times (Yes in S310), the film forming process S206 is terminated.

Subsequently, an operation of the pressure detection unit in the film forming process S206 will be described. When a combination of the first gas supply/exhaust structure 240 and the second gas supply/exhaust structure 280 is increased to realize high throughput, a distance between the neighboring supply/exhaust structures may be reduced and the gases may be mixed.

When the distance between the neighboring first and second gas supply structures 241 and 281 is reduced, the exhaust of the first gas or the second gas may become insufficient. Therefore, the first gas and the second gas may be mixed in the process chamber, the exhaust channel or the exhaust pipe. In this case, the first gas and the second gas are introduced into the first gas exhaust channel 246 or the second gas exhaust channel 286, a chemical vapor deposition (CVD) reaction occurs in the gas exhaust channel or in the exhaust pipe, and a film is attached to a wall surface. When an amount of attachment is increased, abnormality such as clogging of the gas exhaust channel or the exhaust pipe is caused. Since an exhausted flow rate becomes insufficient due to the clogging, process conditions such as a flow velocity or pressure are changed compared to the regions (spaces) below the other gas supply/exhaust structures. Thus, characteristics of the film formed in each of the regions (spaces) below the gas supply/exhaust structures may be changed and lead to reduction in yield.

Thus, in the present embodiment, the abnormal state of the gas exhaust channel or the exhaust pipe is detected to make the process conditions equal to the other region in which the same gas is supplied. Hereinafter, details will be described giving the first gas exhaust unit 270 by way of example.

The first gas exhaust unit 270 exhausts an atmosphere of the region (space) below the gas supply/exhaust structure 240a via a gas exhaust channel 246a and the exhaust pipe 244a. The exhaust pipe 244a is connected to the upstream side exhaust pipe 271a, and the pressure detector 277a detects a pressure P11a when the atmosphere passes through the exhaust pipe 271a. Similarly, an atmosphere of the region below the gas supply/exhaust structure 240b is exhausted through the exhaust pipe 271b, and the pressure detector 277b detects a pressure P11b. Further, an atmosphere of the region below the gas supply/exhaust structure 240c is exhausted through the exhaust pipe 271c, and the pressure detector 277c detects a pressure P11c.

Pressure data detected by each of the pressure detector 277a, the pressure detector 277b and the pressure detector 277c is sent to the controller 400. The controller 400 compares a value detected by each pressure detection unit with pressure data previously recorded in the storage unit.

As previously stored pressure data, for example, three-stage pressure data α1, β1 and γ1 are stored. A relation between these is α1<β1<γ1. α1 is the upper limit of a typical pressure value for forming a film on the wafer 200 using a first gas. When the detected pressure value is lower than α1, the detected pressure is regarded as a typical pressure range. When the detected pressure value is β1, the detected pressure is a pressure that has no influence on a film quality of the wafer, but it is regarded as a pressure higher than the typical pressure α1. When the pressure value is β1, the controller 400 continues processing together with informing a user of a warning on an attached display screen. The apparatus is stopped before wafers of the next lot are processed. During the stop of the apparatus, maintenance, for instance, exchanging the exhaust pipe from which a high pressure value is detected is performed. γ1 is a pressure value that influences the wafer processing. When the pressure value is γ1, it is determined that this exceeds a level at which the pipe has an influence on the film quality, and the apparatus is immediately stopped without waiting for the next lot. The immediate stop inhibits the gas from being introduced into the other pipes.

Similar to the second gas exhaust unit 310, an atmosphere of the region below the gas supply/exhaust structure 280a is exhausted via the exhaust pipe 311a. Along with this, the pressure detector 317a detects a pressure P21a when the atmosphere passes through the exhaust pipe 311a. Further, an atmosphere of the region below the gas supply/exhaust structure 280b is exhausted from the exhaust pipe 311b. Along with this, the pressure detector 317b detects a pressure P21b. An atmosphere of the region below the gas supply/exhaust structure 280c is exhausted from the exhaust pipe 311c. Along with this, the pressure detector 317c detects a pressure P21c.

Pressure data detected by each of the pressure detector 317a, the pressure detector 317b and the pressure detector 317c is sent to the controller 400. The controller 400 compares a value detected by each pressure detection unit with pressure data previously recorded in the storage unit.

As previously stored pressure data, for example, three-stage pressure data α2, β2 and γ2 are stored. A relation between these is α2<β2<γ2. α2 is the upper limit of a typical pressure value for reacting a second gas on the wafer. When the first gas is a source gas and the second gas is a reactive gas, α2 is preferably a value higher than α1 in order to increase reaction efficiency of the reactive gas with respect to the first element-containing layer. When the detected pressure value is lower than α2, the detected pressure is regarded as a typical pressure range. β2 is higher than α2, and is lower than γ2. The pressure value β2 is a pressure that has no influence on a film quality of the wafer, but it is regarded as a pressure value high than the typical pressure α2. When the pressure value is β2, the controller 400 continues processing together with informing a user of a warning on an attached display screen. The apparatus is stopped before wafers of the next lot are processed. During the stop of the apparatus, maintenance, for instance, exchanging the exhaust pipe from which a high pressure value is detected is performed. When the detected pressure value is above γ2, it is determined that a state of the pipe exceeds a level at which the pipe has an influence on the film quality, and the apparatus is immediately stopped without waiting for the next lot. The immediate stop inhibits the gas from being introduced into the other pipes.

[Stop Supplying Gas (S208)]

After the film forming process S206, the valve 256 is at least closed, and supply of the first element-containing gas is stopped. In conjunction with this, the valve 296 is closed, and supply of the second element-containing gas is stopped.

[Stop Rotating Susceptor (S210)]

After the gas supply is stopped (S208), the rotation of the susceptor 220 is stopped. Thereby, the thin film forming process S104 is terminated.

[Substrate Unloading Process S106]

Next, the susceptor 220 is lowered to support the wafer 200 on the wafer elevation pins 224 protruding from the surface of the susceptor 220. Afterwards, a predetermined gate valve is opened, and the wafer 200 is unloaded outside the reaction vessel 203 using the first conveyance robot 112. Afterwards, when the process of processing the substrate is terminated, supply of the inert gas into the process room 201 through the inert gas supply system is stopped.

With the configuration as described above, it can be reliably detected whether the exhaust pipes corresponding to the first gas supply/exhaust structure 240a, the first gas supply/exhaust structure 240b and the first gas supply/exhaust structure 240c are in an abnormal state. Thus, the pressure conditions of the region below the first gas supply/exhaust structure 240a, the region below the first gas supply/exhaust structure 240b and the region below the first gas supply/exhaust structure 240c can be maintained within a constant range.

Further, it can be reliably detected whether the exhaust pipes corresponding to the second gas supply/exhaust structure 280a, the second gas supply/exhaust structure 280b and the second gas supply/exhaust structure 280c are in an abnormal state. Thus, the pressure conditions of the region below the second gas supply/exhaust structure 280a, the region below the second gas supply/exhaust structure 280b and the region below the second gas supply/exhaust structure 280c can be maintained within a constant range.

Furthermore, since the pressure conditions of the region below each of the first gas supply/exhaust structures 240 and the region below each of the second gas supply/exhaust structures 280 can be maintained within a constant range, the characteristics of the layer in the thickness direction of the layer can be made uniform, and the yield can be improved.

Further, when the process continues in the abnormal state such as clogging, it is thought that the gas flows back into the neighboring exhaust channel or exhaust pipe and the abnormal state further occurs. However, in the present embodiment, such a situation can be prevented. For example, when the first gas and the second gas are mixed in the region below the second gas supply/exhaust structure 280a and the clogging occurs in the exhaust pipe 284, the first and second gases originally to be exhausted move to the region below the neighboring first gas supply/exhaust structure 240a or first gas supply/exhaust structure 240b. The moving first and second gases flow into the exhaust pipes of the respective gases, and the film is attached to the gas exhaust channel or the exhaust pipe. When an amount of attachment is increased, the clogging occurs in the gas exhaust channel or the exhaust pipe. When the clogging occurs at one gas supply/exhaust structure in this way, the clogging occurs at the neighboring supply/exhaust structure. As a result, particles occur in the process room 201. In the present embodiment, this situation can be prevented.

Further, in the present embodiment, a more remarkable effect is exerted when a liquid raw material is used as the first gas. Hereinafter, when the liquid raw material is used, the gas supply/exhaust structure and the reason why the remarkable effect is exerted will be described.

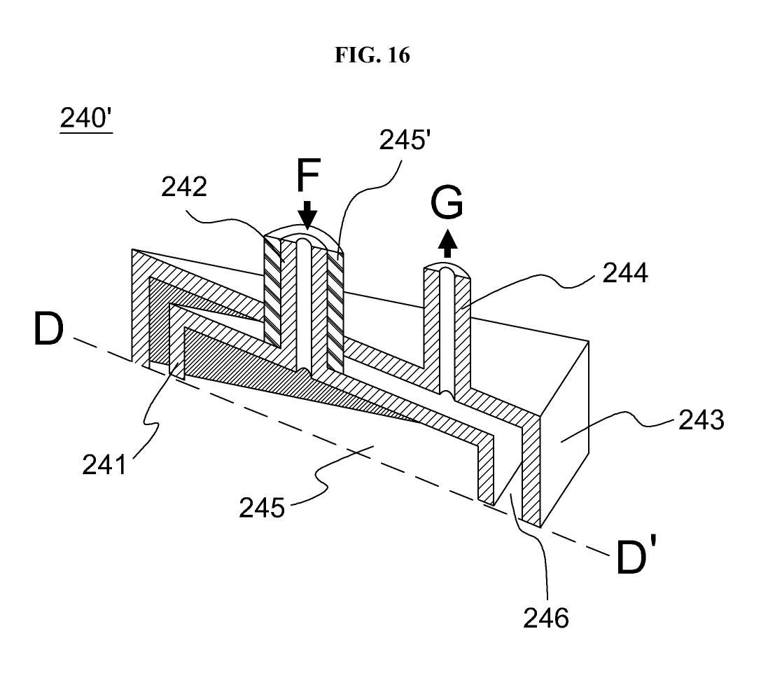

When the liquid raw material is used, a first gas exhaust structure 240′ as in FIG. 16 is used in place of the first gas supply/exhaust structure 240 illustrated in FIGS. 4 and 6. The first gas exhaust structure 240′ is different from those of FIGS. 4 and 6 in that a heater 245′ acting as a temperature controller is provided around the supply pipe 242.

The first gas that is the liquid raw material is supplied to the supply pipe 242 of the first gas exhaust structure 240′. The liquid raw material is not liquefied at the supply pipe 242 again, and is heated to maintain a gas state by the heater 245′.

The liquid source gas supplied through the gas supply channel 245 forms a film on the wafer 200. The liquid source gas having contributed to the film formation is exhausted via the exhaust channel 246, the exhaust pipe 244 and the exhaust pipe 271, but the exhaust pipe 244 or the exhaust pipe 271 is not heated and thus has a low temperature compared to the supply pipe. For this reason, the gas is thought to be liquefied again. The liquid raw material liquefied again may be attached to the exhaust pipe 244 and the exhaust pipe 271, and cause pipe abnormality such as clogging.

In the present embodiment, the pipe abnormality can be reliably detected with respect to this situation. Thus, even when the liquid raw material requiring delicate temperature control is used, it is possible to prevent a reduction in operation efficiency.

### Second Embodiment of the Present Invention

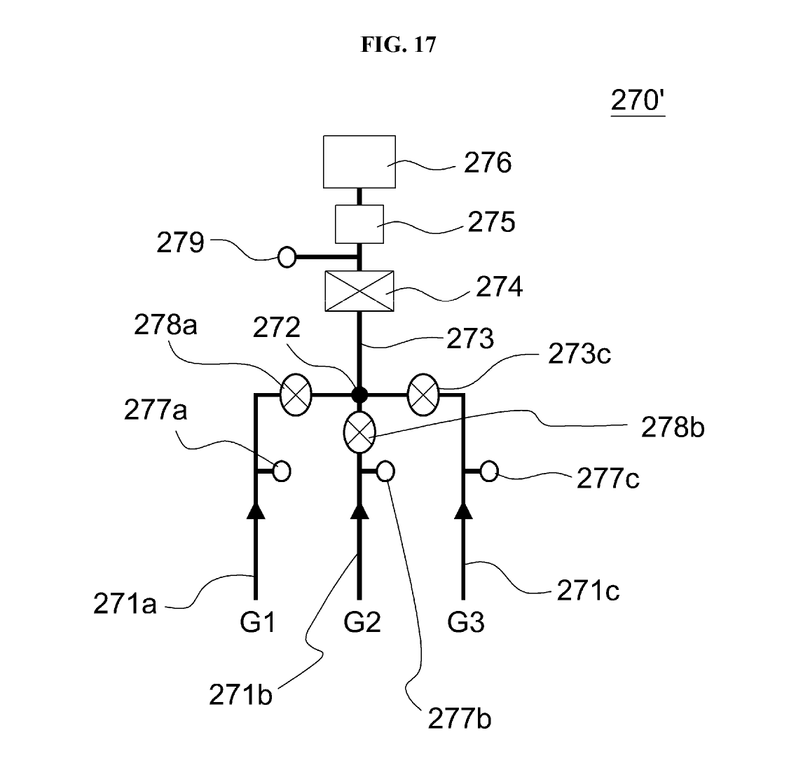

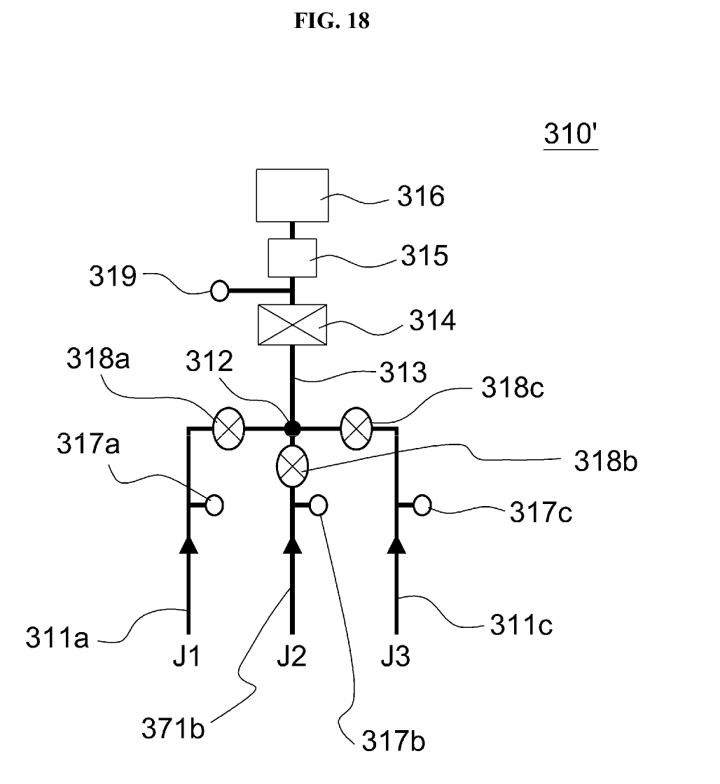

Subsequently, a second embodiment will be described. In the second embodiment, the exhaust unit 270 of the first embodiment is replaced with an exhaust unit 270′, and the exhaust unit 310 of the first embodiment is replaced with an exhaust unit 310′. As illustrated in FIG. 17, the exhaust unit 270′ has a valve 278a, a valve 278b, a valve 278c and a pressure detector 279 that are added to the components of the exhaust unit 270. As illustrated in FIG. 18, the exhaust unit 310′ has a valve 318a, a valve 318b, a valve 318c and a pressure detector 319 that are added to the components of the exhaust unit 310.

Subsequently, a method of detecting abnormality of the pipe will be described. The abnormality mentioned herein refers to, for instance, clogging of the pipe as in the first embodiment. An abnormality detecting process of the present embodiment is performed in a maintenance process to be described below after the process of FIG. 13 is terminated.

[Maintenance Process]

In the maintenance process, abnormality of the exhaust pipe is detected. First, a method of detecting abnormality of the exhaust unit 270′ will be described. After the substrate processing is terminated, the valve 278a is set to be opened, and the valve 278b and the valve 278c are set to be closed. In conjunction with this, the valve 318a, the valve 318b and the valve 318c are set to be closed.

Thereafter, an inert gas is supplied to the process chamber through a gas supply channel 245a, and the supplied gas is exhausted via a gas exhaust channel 246a and an exhaust pipe 271a. When the gas is exhausted, a pressure of the exhaust pipe 271a is detected by a pressure detection unit 277a. Further, a pressure of an exhaust pipe 273 is detected by a pressure detection unit 279. Each of the detected pressure data is sent to a controller 400. A difference ΔP1a between a value of the pressure detected by the pressure detection unit 277a and a value of the pressure detected by the pressure detection unit 279 is calculated at the controller 400. The calculated data is compared with pre-stored pressure data for maintenance. The pressure data for maintenance includes, for instance, an upper limit α3a of a processible state and β3a of an abnormal state. When ΔP1a is within a range of α3a, this is determined to be in a wafer processible state. When ΔP1a is within a range of β3a, this is determined to be in an abnormal state, and maintenance such as exchanging or cleaning of the pipe is performed.

Next, the valve 278a and the valve 278c are set to be closed, and the valve 278b is set to be opened. Thereafter, an inert gas is supplied to the process chamber through a gas supply channel 245b, and the supplied gas is exhausted via a gas exhaust channel 246b and an exhaust pipe 271b. When the gas is exhausted, a pressure of the exhaust pipe 271b is detected by a pressure detection unit 277b. Further, the pressure of the exhaust pipe 273 is detected by the pressure detection unit 279. Each of the detected pressure data is sent to the controller 400. A difference ΔP1b between a value of the pressure detected by the pressure detection unit 277b and a value of the pressure detected by the pressure detection unit 279 is calculated at the controller 400. The calculated data is compared with pre-stored pressure data for maintenance. The pressure data for maintenance includes, for instance, an upper limit α3b of a processible state and β3b of an abnormal state. When ΔP1b is within a range of α3b, this is determined to be in a wafer processible state. When ΔP1b is within a range of β3b, this is determined to be in an abnormal state, and maintenance such as exchanging or cleaning of the pipe is performed.

Next, the valve 278a and the valve 278b are set to be closed, and the valve 278c is set to be opened. Thereafter, an inert gas is supplied to the process chamber through a gas supply channel 245c, and the supplied gas is exhausted via a gas exhaust channel 246c and an exhaust pipe 271c. When the gas is exhausted, a pressure of the exhaust pipe 271c is detected by a pressure detection unit 277c. Further, the pressure of the exhaust pipe 273 is detected by the pressure detection unit 279. Each of the detected pressure data is sent to the controller 400. A difference ΔP1c between a value of the pressure detected by the pressure detection unit 277c and a value of the pressure detected by the pressure detection unit 279 is calculated at the controller 400. The calculated data is compared with pre-stored pressure data for maintenance. The pressure data for maintenance includes, for instance, an upper limit α3c of a processible state and β3c of an abnormal state. When ΔP1c is within a range of α3c, this is determined to be in a wafer processible state. When ΔP1c is within a range of β3c, this is determined to be in an abnormal state, and maintenance such as exchanging or cleaning of the pipe is performed.

The abnormality of the exhaust unit 270′ is detected by the method as described above.

Next, a method of detecting abnormality of the exhaust unit 310′ will be described. After the abnormality detection of the exhaust unit 270′ is terminated, the valve 278a, the valve 278b and the valve 278c are set to be closed. In conjunction with this, the valve 318a is set to be opened, and the valve 318b and the valve 318c are set to be closed.

Thereafter, an inert gas is supplied to the process chamber through a gas supply channel 285a, and the supplied gas is exhausted via a gas exhaust channel 286a and an exhaust pipe 311a. When the gas is exhausted, a pressure of the exhaust pipe 311a is detected by a pressure detection unit 317a. Further, a pressure of an exhaust pipe 313 is detected by a pressure detection unit 319. Each of the detected pressure data is sent to the controller 400. A difference ΔP2a between a value of the pressure detected by the pressure detection unit 317a and a value of the pressure detected by the pressure detection unit 319 is calculated at the controller 400. The calculated data is compared with pre-stored pressure data for maintenance. The pressure data for maintenance includes, for instance, an upper limit α4a of a processible state and β4a of an abnormal state. When ΔP2a is within a range of α4a, this is determined to be in a wafer processible state. When ΔP2a is within a range of β4a, this is determined to be in an abnormal state, and maintenance such as exchanging or cleaning of the pipe is performed.

Next, the valve 318a and the valve 318c are set to be closed, and the valve 318b is set to be opened. Thereafter, an inert gas is supplied to the process chamber through a gas supply channel 285, and the supplied gas is exhausted via a gas exhaust channel 286b and an exhaust pipe 311b. When the gas is exhausted, a pressure of the exhaust pipe 311b is detected by a pressure detection unit 317b. Further, the pressure of the exhaust pipe 273 is detected by the pressure detection unit 319. Each of the detected pressure data is sent to the controller 400. A difference ΔP2b between a value of the pressure detected by the pressure detection unit 317b and a value of the pressure detected by the pressure detection unit 319 is calculated at the controller 400. The calculated data is compared with pre-stored pressure data for maintenance. The pressure data for maintenance includes, for instance, an upper limit α4b of a processible state and β4b of an abnormal state. When ΔP2b is within a range of α4b, this is determined to be in a wafer processible state. When ΔP2b is within a range of β4b, this is determined to be in an abnormal state, and maintenance such as exchanging or cleaning of the pipe is performed.

Next, the valve 318a and the valve 318b are set to be closed, and the valve 318c is set to be opened. Thereafter, an inert gas is supplied to the process chamber through a gas supply channel 285, and the supplied gas is exhausted via a gas exhaust channel 286c and an exhaust pipe 311c. When the gas is exhausted, a pressure of the exhaust pipe 311c is detected by a pressure detection unit 317c. Further, the pressure of the exhaust pipe 313 is detected by the pressure detection unit 319. Each of the detected pressure data is sent to the controller 400. A difference ΔP2c between a value of the pressure detected by the pressure detection unit 317c and a value of the pressure detected by the pressure detection unit 319 is calculated at the controller 400. The calculated data is compared with pre-stored pressure data for maintenance. The pressure data for maintenance includes, for instance, an upper limit α4c of a processible state and β4c of an abnormal state. When ΔP2c is within a range of α4c, this is determined to be in a wafer processible state. When ΔP2c is within a range of β4c, this is determined to be in an abnormal state, and maintenance such as exchanging or cleaning of the pipe is performed.

The abnormality of the exhaust unit 310′ is detected by the method as described above.

In this way, the pressure is detected at each of the upstream side exhaust pipe 271 and the downstream side exhaust pipe 273, and thereby the abnormality can be discovered upstream as well as downstream from the pressure detector 277.

Further, since the abnormality can be discovered at each of the upstream side exhaust pipe 271a, the upstream side exhaust pipe 271b and the upstream side exhaust pipe 271c, it is possible to increase maintenance efficiency.

### Other Embodiments of the Present Invention

Although the embodiments of the present invention have been described, the present invention is not limited to each of the aforementioned embodiments.

Further, for example, in each of the aforementioned embodiments, the structure in which relative positions of each wafer 200 on the susceptor 220 and each gas supply structure are displaced by rotating the susceptor 220 is given as an example, but the present invention is not limited thereto. That is, in the present invention, as long as the relative positions of each wafer on the substrate support table 220 and each gas supply structure are displaced, the rotary drive system described in each embodiment is not necessarily employed. For example, the ceiling of the process chamber in which the gas supply structures are fixed may be rotated.

Further, for example, in each of the aforementioned embodiments, the example in which, as the film forming process which the substrate processing apparatus performs, the TiCl₄ gas is used as the source gas (first process gas), the NH₃ gas is used as the reactive gas (second process gas), and these gases are alternately supplied to form the TiN film on the wafer W is given, the present invention is not limited thereto. That is, the process gas used for the film forming process is not limited to the TiCl₄ gas or the NH₃ gas, and another type of thin film may be formed using another type of gas. Further, even when three or more process gases are used, the present invention may be applied as long as the process gases are alternately supplied to perform the film forming process.

Further, in the above embodiments, the process conditions are described to be the same. This consequently refers to conditions on which the characteristics of the substrate are within a desired range. Thus, the meaning that the process conditions are set to be the same indicates a range of the conditions on which the characteristics of the substrate are within a desired range.

Further, for example, in each of the aforementioned embodiments, as the process which the substrate processing apparatus performs, the film forming process is given as an example, but the present invention is not limited thereto. That is, in addition to the film forming process, a process of forming an oxide film or a nitride film, or a process of forming a film including a metal may be used. Further, the details of the process of processing the substrate are not restricted at all, and may be properly applied to the film forming process as well as another process of processing the substrate such as an annealing process, an oxidizing process, a nitriding process, a diffusing process or a lithography process. Further, the present invention may be properly applied to another substrate processing apparatus, for instance, an annealing apparatus, an oxidizing apparatus, a nitriding apparatus, an exposing apparatus, a coating apparatus, a drying apparatus, a heating apparatus or a processing apparatus using plasma. Further, in the present invention, these apparatuses may be mixed. Further, some of the components of any embodiment may be substituted with the components of the other embodiment. Further, the components of the other embodiment may be added to the components of any embodiment. Further, the other components may be added, deleted, or substituted with respect to some of the components of each embodiment.

According to the present invention, it is possible to inhibit a film having inconsistent characteristics from being formed to process a substrate at a high yield.

### Preferred Embodiments of the Present Invention

Hereinafter, preferred embodiments according to the present invention are supplementarily noted.

<Supplementary Note 1>

According to an aspect of the present invention, there is provided a substrate processing apparatus including:

a process chamber;

a substrate support table disposed in the process chamber, the substrate support table including circumferentially arranged substrate placement units;

a rotation unit configured to rotate the substrate support table;

a plurality of source gas supply structures circumferentially arranged above the substrate support table;

a source gas supply unit configured to supply a source gas to a region below the plurality of source gas supply structures via the plurality of source gas supply structures;

a plurality of source gas exhaust structures configured to exhaust an atmosphere of the region below the plurality of source gas supply structures, wherein each source gas exhaust structure corresponds to each source gas supply structure;

a plurality of source gas exhaust pipes connected to the plurality of source gas exhaust structures, wherein each source gas exhaust pipe is connected to each source gas exhaust structure;

a source gas exhaust unit configured to exhaust an atmosphere of the process chamber via the plurality of source gas exhaust structures;

a plurality of reactive gas supply structures disposed between the plurality of source gas supply structures above the substrate support table;

a reactive gas supply unit configured to supply a reactive gas to a region below the plurality of reactive gas supply structures via the plurality of reactive gas supply structures;

a plurality of reactive gas exhaust structures configured to exhaust an atmosphere of the region below the plurality of reactive gas supply structures, wherein each reactive gas exhaust structure corresponds to each reactive gas supply structure;

a plurality of reactive gas exhaust pipes connected to the plurality of reactive gas exhaust structures, wherein each reactive gas exhaust pipe is connected to each reactive gas exhaust structure;

a reactive gas exhaust unit configured to exhaust the atmosphere of the process chamber via the plurality of reactive gas exhaust structures;

a plurality of reactive gas pressure detectors installed at the plurality of reactive gas exhaust pipes; and

a controller configured to control at least the source gas supply unit, the source gas exhaust unit, the reactive gas supply unit, the reactive gas exhaust unit and the plurality of reactive gas pressure detectors.

<Supplementary Note 2>

In the substrate processing apparatus of Supplementary note 1, preferably, further including a plurality of source gas pressure detectors installed at the plurality of source gas exhaust pipes.

<Supplementary Note 3>

In the substrate processing apparatus of any one of Supplementary notes 1 and 2, preferably, the controller is configured to determine at least one of the plurality of reactive gas exhaust pipes as abnormal when pressure of the at least one of the plurality of reactive gas exhaust pipes detected by the plurality of reactive gas pressure detector is higher than a predetermined value.

<Supplementary Note 4>

In the substrate processing apparatus of any one of Supplementary notes 2 and 3, preferably, the controller is configured to determine at least one of the plurality of source gas exhaust pipes as abnormal when pressure of the at least one of the plurality of source gas exhaust pipes detected by the plurality of source gas pressure detector is higher than a predetermined value.

<Supplementary Note 5>

In the substrate processing apparatus of any one of Supplementary notes 1 through 4, preferably, further including:

a first confluence part where the plurality of reactive gas exhaust pipes are joined;

a reactive gas confluence pipe connected to a downstream side of the first confluence part; and

a reactive gas confluence pipe pressure detector installed at the reactive gas confluence pipe.

<Supplementary Note 6>

In the substrate processing apparatus of Supplementary note 5, preferably, further including a first valve installed between the plurality of reactive gas pressure detectors and the first confluence part.

<Supplementary Note 7>

In the substrate processing apparatus of any one of Supplementary notes 2 through 6, preferably, further including:

a second confluence part where the plurality of source gas exhaust pipes are joined;

a source gas confluence pipe connected to a downstream side of the second confluence part; and

a source gas confluence pipe pressure detector installed at the source gas confluence pipe.

<Supplementary Note 8>

In the substrate processing apparatus of Supplementary note 7, preferably, further including a second valve installed between the plurality of source gas pressure detectors and the second confluence part.

<Supplementary Note 9>

According to another aspect of the present invention, preferably, there is provided a method of manufacturing s semiconductor device including:

a) loading a plurality of substrates into a process chamber and circumferentially arranging the plurality of substrates on a substrate support table accommodated in the process chamber;

b) rotating the substrate support table;

c) supplying a source gas to a region below a plurality of source gas supply structures via the plurality of source gas supply structures, and exhausting an atmosphere of the region below the plurality of source gas supply structures, wherein each source gas exhaust structure corresponds to each source gas supply structure; and

d) supplying a reactive gas to a region below a plurality of reactive gas supply structures via the plurality of reactive gas supply structures, and exhausting an atmosphere of the region below the plurality of reactive gas supply structures while performing c, wherein each reactive gas exhaust structure corresponds to each reactive gas supply structure,

wherein pressures of a plurality of reactive gas exhaust pipes, wherein each reactive gas exhaust pipe is connected to each reactive gas exhaust structure, are detected in d).

<Supplementary Note 10>

According to still another aspect of the present invention, preferably, there is provided a program executed in a substrate processing apparatus, the program causing the substrate processing apparatus to perform:

a) loading a plurality of substrates into a process chamber and circumferentially arranging the plurality of substrates on a substrate support table accommodated in the process chamber;

b) rotating the substrate support table;

c) supplying a source gas to a region below a plurality of source gas supply structures via the plurality of source gas supply structures, and exhausting an atmosphere of the region below the plurality of source gas supply structures, wherein each source gas exhaust structure corresponds to each source gas supply structure; and

d) supplying a reactive gas to a region below a plurality of reactive gas supply structures via the plurality of reactive gas supply structures, and exhausting an atmosphere of the region below the plurality of reactive gas supply structures while performing c, wherein each reactive gas exhaust structure corresponds to each reactive gas supply structure,

wherein pressures of a plurality of reactive gas exhaust pipes, wherein each reactive gas exhaust pipe is connected to each reactive gas exhaust structure, are detected in d).

<Supplementary Note 11>

According to still another aspect of the present invention, preferably, there is provided a non-transitory computer-readable recording medium storing a program executed in a substrate processing apparatus, the program causing the substrate processing apparatus to perform:

a) loading a plurality of substrates into a process chamber and circumferentially arranging the plurality of substrates on a substrate support table accommodated in the process chamber;

b) rotating the substrate support table;

c) supplying a source gas to a region below a plurality of source gas supply structures via the plurality of source gas supply structures, and exhausting an atmosphere of the region below the plurality of source gas supply structures, wherein each source gas exhaust structure corresponds to each source gas supply structure; and

d) supplying a reactive gas to a region below a plurality of reactive gas supply structures via the plurality of reactive gas supply structures, and exhausting an atmosphere of the region below the plurality of reactive gas supply structures while performing c, wherein each reactive gas exhaust structure corresponds to each reactive gas supply structure,

wherein pressures of a plurality of reactive gas exhaust pipes, wherein each reactive gas exhaust pipe is connected to each reactive gas exhaust structure, are detected in d).

1. A substrate processing apparatus comprising:
a process chamber;
a substrate support table disposed in the process chamber, the substrate support table including circumferentially arranged substrate placement units;
a rotation unit configured to rotate the substrate support table;
a plurality of source gas supply structures circumferentially arranged above the substrate support table;
a source gas supply unit configured to supply a source gas to a region below the plurality of source gas supply structures via the plurality of source gas supply structures, the source gas supply unit comprising a source gas supply pipe connected to the plurality of source gas supply structures;
a plurality of source gas exhaust structures configured to exhaust an atmosphere of the region below the plurality of source gas supply structures, wherein each source gas exhaust structure corresponds to each source gas supply structure;
a plurality of source gas exhaust pipes connected to the plurality of source gas exhaust structures, wherein each source gas exhaust pipe is connected to each source gas exhaust structure;
a source gas exhaust unit configured to exhaust an atmosphere of the process chamber via the plurality of source gas exhaust structures;
a plurality of reactive gas supply structures disposed above the substrate support table, wherein each the plurality of reactive gas supply structures and each of the plurality of source gas supply structures are alternately arranged;
a reactive gas supply unit configured to supply a reactive gas to a region below the plurality of reactive gas supply structures via the plurality of reactive gas supply structures;
a plurality of reactive gas exhaust structures configured to exhaust an atmosphere of the region below the plurality of reactive gas supply structures, wherein each reactive gas exhaust structure corresponds to each reactive gas supply structure;
a plurality of reactive gas exhaust pipes connected to the plurality of reactive gas exhaust structures, wherein each reactive gas exhaust pipe is connected to each reactive gas exhaust structure;
a reactive gas exhaust unit configured to exhaust the atmosphere of the process chamber via the plurality of reactive gas exhaust structures;
a plurality of reactive gas pressure detectors installed at the plurality of reactive gas exhaust pipes and configured to detect a pressure of the reactive gas;
a storage unit configured to store a reactive gas pressure value representing the pressure of the reactive gas in a normal state and a reactive gas pressure value representing the pressure of the reactive gas in an abnormal state; and
a controller configured to control at least the source gas supply unit, the source gas exhaust unit, the reactive gas supply unit, the reactive gas exhaust unit and the plurality of reactive gas pressure detectors and configured to compare the pressure of the reactive gas detected by the plurality of reactive gas pressure detectors to the reactive gas pressure value stored in the storage unit.

2. The substrate processing apparatus of claim 1, further comprising a plurality of source gas pressure detectors installed at the plurality of source gas exhaust pipes and configured to detect a pressure of the source gas, wherein the storage unit is further configured to store a source gas pressure value representing the pressure of the source gas in the normal state and a source gas pressure value representing the pressure of the source gas in the abnormal state, and the controller is further configured to compare the pressure of the source gas detected by the plurality of source gas pressure detectors to the source gas pressure value stored in the storage unit.

3. The substrate processing apparatus of claim 2, wherein the controller is configured to determine at least one of the plurality of reactive gas exhaust pipes as abnormal when the pressure of the reactive gas detected by the plurality of reactive gas pressure detectors is the same as the reactive gas pressure value representing the pressure of the reactive gas in the abnormal state.

4. The substrate processing apparatus of claim 3, wherein the controller is configured to determine at least one of the plurality of source gas exhaust pipes as abnormal when the pressure of the source gas detected by the plurality of source gas pressure detectors is the same as the source gas pressure value representing the pressure of the source gas in the abnormal state.

5. The substrate processing apparatus of claim 4, further comprising:
a first confluence part where the plurality of reactive gas exhaust pipes are joined;
a reactive gas confluence pipe connected to a downstream side of the first confluence part; and
a reactive gas confluence pipe pressure detector installed at the reactive gas confluence pipe.

6. The substrate processing apparatus of claim 5, further comprising a first valve installed between the plurality of reactive gas pressure detectors and the first confluence part.

7. The substrate processing apparatus of claim 6, further comprising:
a second confluence part where the plurality of source gas exhaust pipes are joined;
a source gas confluence pipe connected to a downstream side of the second confluence part; and
a source gas confluence pipe pressure detector installed at the source gas confluence pipe.

8. The substrate processing apparatus of claim 7, further comprising a second valve installed between the plurality of source gas pressure detectors and the second confluence part.

9. The substrate processing apparatus of claim 2, wherein the controller is configured to determine at least one of the plurality of source gas exhaust pipes as abnormal when the pressure of the source gas detected by the plurality of source gas pressure detectors is same as the source gas pressure value representing the pressure of the source gas in the abnormal state.

10. The substrate processing apparatus of claim 9, further comprising:
a second confluence part where the plurality of source gas exhaust pipes are joined;
a source gas confluence pipe connected to a downstream side of the second confluence part; and
a source gas confluence pipe pressure detector installed at the source gas confluence pipe.

11. The substrate processing apparatus of claim 10, further comprising a second valve installed between the plurality of source gas pressure detectors and the second confluence part.

12. The substrate processing apparatus of claim 1, wherein the controller is configured to determine at least one of the plurality of reactive gas exhaust pipes as abnormal when the pressure of the reactive gas detected by the plurality of reactive gas pressure detectors is the same as the reactive gas pressure value representing the pressure of the reactive gas in the abnormal state.

13. The substrate processing apparatus of claim 12, further comprising:
a first confluence part where the plurality of reactive gas exhaust pipes are joined;
a reactive gas confluence pipe connected to a downstream side of the first confluence part; and
a reactive gas confluence pipe pressure detector installed at the reactive gas confluence pipe.

14. The substrate processing apparatus of claim 13, further comprising a first valve installed between the plurality of reactive gas pressure detectors and the first confluence part.

15. A non-transitory computer-readable recording medium storing a program executed in a substrate processing apparatus, the program causing the substrate processing apparatus to perform:
(a) loading a plurality of substrates into a process chamber and circumferentially arranging the plurality of substrates on a substrate support table accommodated in the process chamber;
(b) rotating the substrate support table;
(c) supplying a source gas to a region below a plurality of source gas supply structures via the plurality of source gas supply structures, and exhausting an atmosphere of the region below the plurality of source gas supply structures, wherein each source gas exhaust structure corresponds to each source gas supply structure; and
(d) supplying a reactive gas to a region below a plurality of reactive gas supply structures via the plurality of reactive gas supply structures, and exhausting an atmosphere of the region below the plurality of reactive gas supply structures while performing (c), wherein each reactive gas exhaust structure corresponds to each reactive gas supply structure,
wherein pressures of a plurality of reactive gas exhaust pipes, wherein each reactive gas exhaust pipe is connected to each reactive gas exhaust structure, are detected in (d).

16. The substrate processing apparatus of claim 4, wherein the controller is further configured to stop an operation of the substrate processing apparatus when the pressure of the source gas detected by the plurality of source gas pressure detectors is at a level influencing a film quality.

17. The substrate processing apparatus of claim 12, wherein the controller is further configured to stop an operation of the substrate processing apparatus when the pressure of the reactive gas detected by the plurality of reactive gas pressure detectors is at a level influencing a film quality.

18. The substrate processing apparatus of claim 1, further comprising a liquid source supply pipe having a heater and connected to the source gas supply pipe.
